(19) United States
(12) Patent Application Publication
(10) Pub. No.: US 2016/0078940 A1
(43) Pub. Date: Mar. 17, 2016

(54) NONVOLATILE SEMICONDUCTOR MEMORY DEVICE AND METHOD OF MANUFACTURING NONVOLATILE SEMICONDUCTOR MEMORY DEVICE

(71) Applicant: Kabushiki Kaisha Toshiba, Minato-ku (JP)

(72) Inventors: Naoya KAMI, Fujisawa (JP); Kazunori Masuda, Yokohama (JP); Yuuichi Tatsumi, Setagaya (JP); Naoyuki Kondo, Kamakura (JP); Masato Endo, Yokohama (JP); Yukio Nishida, Yokohama (JP)

(73) Assignee: Kabushiki Kaisha Toshiba, Minato-ku (JP)

(21) Appl. No.: 14/615,643

(22) Filed: Feb. 6, 2015

(30) Foreign Application Priority Data
Sep. 11, 2014 (JP) 2014-185593

(51) Int. Cl. G11C 16/04; H01L 21/768

(52) U.S. Cl. CPC G11C 16/0483; H01L 21/76895

(57) ABSTRACT

According to one embodiment, a nonvolatile semiconductor memory device includes first word lines equipped with flag-like portions on one side of the block in the row direction and equipped with no flag-like portions on the other side of the block in the row direction, and second word lines equipped with no flag-like portions on the one side of the block in the row direction and equipped with flag-like portions on the other side of the block in the row direction.

### CROSS-REFERENCE TO RELATED APPLICATIONS

This application is based upon and claims the benefit of priority from Japanese Patent Application No. 2014-185593, filed on Sep. 11, 2014; the entire contents of which are incorporated herein by reference.

### FIELD

Embodiments described herein relate generally to a nonvolatile semiconductor memory device and a method of manufacturing a nonvolatile semiconductor memory device.

### BACKGROUND

As a nonvolatile semiconductor memory device, there is a type provided with a hookup section that connects word lines to a decoder via contacts. If the contact width becomes larger than the line width of the word lines because of line thinning of the word lines, the hookup section needs to include flag-like portions in a direction perpendicular to the word line direction of the memory cell array, which bring about an increase in the layout area of the hookup section.

### BRIEF DESCRIPTION OF THE DRAWINGS

FIG. 1 is a block diagram showing a schematic configuration of a nonvolatile semiconductor memory device according to a first embodiment;

FIG. 2 is a circuit diagram showing a schematic configuration of a block and row decoders arranged in the nonvolatile semiconductor memory device according to the first embodiment;

FIG. 3 is a sectional view showing a schematic configuration of one NAND cell of the nonvolatile semiconductor memory device shown in FIG. 1;

FIG. 4 is a plan view showing a layout configuration of word lines in blocks and hookup sections for three blocks in the nonvolatile semiconductor memory device according to the first embodiment;

FIG. 5 is a plan view showing a method of manufacturing the nonvolatile semiconductor memory device according to the first embodiment;

FIG. 6 is a plan view showing the method of manufacturing the nonvolatile semiconductor memory device according to the first embodiment;

FIG. 7 is a plan view showing the method of manufacturing the nonvolatile semiconductor memory device according to the first embodiment;

FIG. 8 is a plan view showing the method of manufacturing the nonvolatile semiconductor memory device according to the first embodiment;

FIG. 9 is a plan view showing the method of manufacturing the nonvolatile semiconductor memory device according to the first embodiment;

FIG. 10 is a plan view showing the method of manufacturing the nonvolatile semiconductor memory device according to the first embodiment;

FIG. 11 is a plan view showing the method of manufacturing the nonvolatile semiconductor memory device according to the first embodiment;

FIG. 12 is a plan view showing the method of manufacturing the nonvolatile semiconductor memory device according to the first embodiment;

FIG. 13 is a circuit diagram showing a schematic configuration of a block and row decoders arranged in a nonvolatile semiconductor memory device according to a second embodiment;

FIG. 14 is a plan view showing a method of manufacturing the nonvolatile semiconductor memory device according to the second embodiment;

FIG. 15 is a plan view showing the method of manufacturing the nonvolatile semiconductor memory device according to the second embodiment;

FIG. 16 is a plan view showing the method of manufacturing the nonvolatile semiconductor memory device according to the second embodiment;

FIG. 17 is a plan view showing the method of manufacturing the nonvolatile semiconductor memory device according to the second embodiment;

FIG. 18 is a plan view showing the method of manufacturing the nonvolatile semiconductor memory device according to the second embodiment;

FIG. 19 is a plan view showing the method of manufacturing the nonvolatile semiconductor memory device according to the second embodiment;

FIG. 20 is a plan view showing the method of manufacturing the nonvolatile semiconductor memory device according to the second embodiment;

FIG. 21 is a plan view showing the method of manufacturing the nonvolatile semiconductor memory device according to the second embodiment;

FIG. 22 is a circuit diagram showing a schematic configuration of blocks and row decoders arranged in a nonvolatile semiconductor memory device according to a third embodiment;

FIG. 23 is a plan view showing a layout configuration of word lines in blocks and hookup sections for three blocks in the nonvolatile semiconductor memory device according to the third embodiment;

FIG. 24 is a plan view showing a method of manufacturing the nonvolatile semiconductor memory device according to the third embodiment;

FIG. 25 is a plan view showing the method of manufacturing the nonvolatile semiconductor memory device according to the third embodiment;

FIG. 26 is a plan view showing the method of manufacturing the nonvolatile semiconductor memory device according to the third embodiment;

FIG. 27 is a plan view showing the method of manufacturing the nonvolatile semiconductor memory device according to the third embodiment;

FIG. 28 is a plan view showing the method of manufacturing the nonvolatile semiconductor memory device according to the third embodiment;

FIG. 29 is a plan view showing the method of manufacturing the nonvolatile semiconductor memory device according to the third embodiment;

FIG. 30 is a plan view showing the method of manufacturing the nonvolatile semiconductor memory device according to the third embodiment; and

FIG. 31 is a plan view showing the method of manufacturing the nonvolatile semiconductor memory device according to the third embodiment.

### DETAILED DESCRIPTION

In general, according to one embodiment, a nonvolatile semiconductor memory device includes a block formed with NAND cells arrayed in a row direction, each of the NAND cells including memory cells connected in series in a column direction, and a hookup section formed with flag-like portions that make contacts with word lines of the memory cells. The word lines include first word lines equipped with flag-like portions on one side of the block in the row direction and equipped with no flag-like portions on the other side of the block in the row direction, and second word lines equipped with no flag-like portions on the one side of the block in the row direction and equipped with flag-like portions on the other side of the block in the row direction. The flag-like portions of the first word lines are arranged at positions more distant from the block as compared with end portions of the second word lines, which include no flag-like portions, on the one side of the block in the row direction, and the flag-like portions of the second word lines are arranged at positions more distant from the block as compared with end portions of the first word lines, which include no flag-like portions, on the other side of the block in the row direction.

Exemplary embodiments of a nonvolatile semiconductor memory device and a method of manufacturing a nonvolatile semiconductor memory device will be explained below in detail with reference to the accompanying drawings. The present invention is not limited to the following embodiments.

### First Embodiment

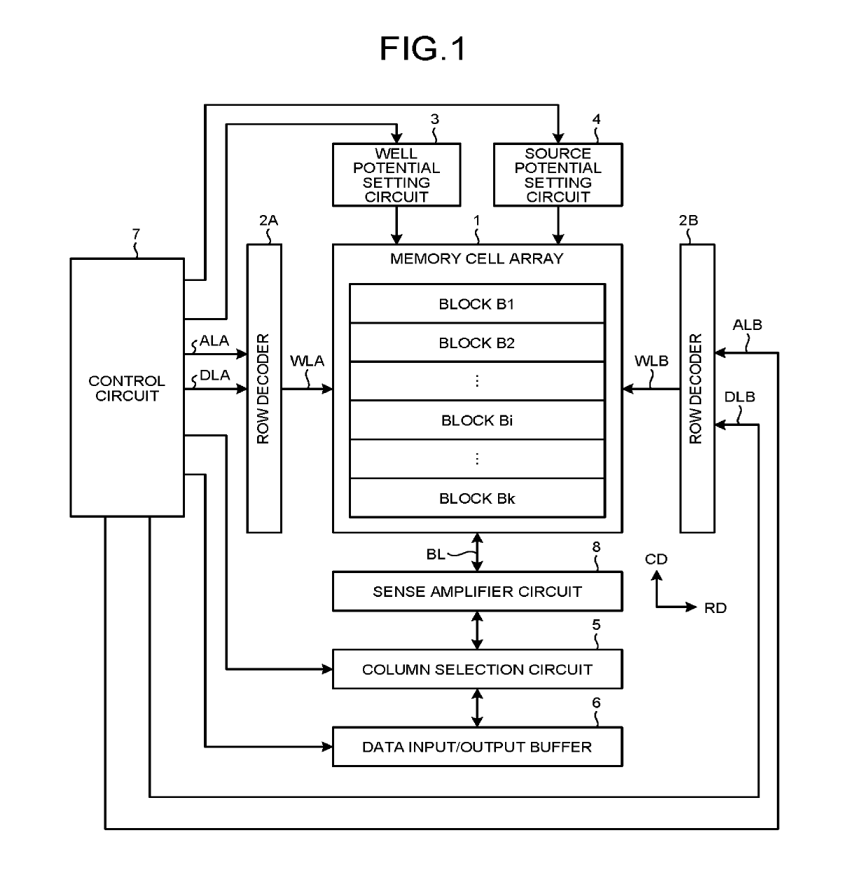

FIG. 1 is a block diagram showing a schematic configuration of a nonvolatile semiconductor memory device according to a first embodiment.

As shown in FIG. 1, this nonvolatile semiconductor memory device is provided with a memory cell array 1, row decoders 2A and 2B, a well potential setting circuit 3, a source potential setting circuit 4, a column selection circuit 5, a data input/output buffer 6, a control circuit 7, and a sense amplifier circuit 8.

In the memory cell array 1, memory cells for storing data are arranged in a matrix format set in a row direction RD and a column direction CD. Each of the memory cells may be designed to store binary data of one bit, or it may be designed in a multi-value type to store multi-value data of two or more bits.

Here, the memory cell array 1 is divided into a “k”-number (“k” is a positive integer) of blocks B1 to Bk. Each of the blocks B1 to Bk may be composed of a plurality of NAND cells arrayed in the row direction RD. Each of the NAND cells may be composed of memory cells connected in series in the column direction CD. Further, the memory cell array 1 includes bit lines BL for transmitting potentials corresponding to data stored the in the memory cells in the column direction CD, and word lines WLA and WLB for transmitting voltages to be applied to the memory cells. It may be designed such that the word lines WLA are connected to the row decoder 2A and the word lines WLB are connected to the row decoder 2B.

Further, each of the row decoders 2A and 2B serves to perform selection of memory cells in the row direction RD of the memory cell array 1, in a read operation, write operation, or erase operation of memory cells. Here, the row decoder 2A receives inputs of a row address ALA and a drive signal DLA. Then, based on the row address ALA, the row decoder 2A can perform selection of the blocks B1 to Bk and transfer the drive signal DLA to the word lines WLA of the selected block. The row decoder 2B receives inputs of a row address ALB and a drive signal DLB. Then, based on the row address ALB, the row decoder 2B can perform selection of the blocks B1 to Bk and transfer the drive signal DLB to the word lines WLB of the selected block. The well potential setting circuit 3 serves to set a well potential in the memory cell array 1, in a read operation, write operation, or erase operation of memory cells. The source potential setting circuit 4 serves to set a source potential in the memory cell array 1, in a read operation, write operation, or erase operation of memory cells. The column selection circuit 5 serves to perform selection of memory cells in the column direction CD of the memory cell array 1, in a read operation, write operation, or erase operation of memory cells. The sense amplifier circuit 8 serves to discriminate data read from memory cells, for every column. The data input/output buffer 6 serves to send commands and/or addresses, which have been received from the outside, to the control circuit 7, and to exchange data between the sense amplifier circuit 8 and the outside. Based on the commands and/or addresses, the control circuit 7 can control the operations of the row decoders 2A and 2B, the well potential setting circuit 3, the source potential setting circuit 4, and the column selection circuit 5.

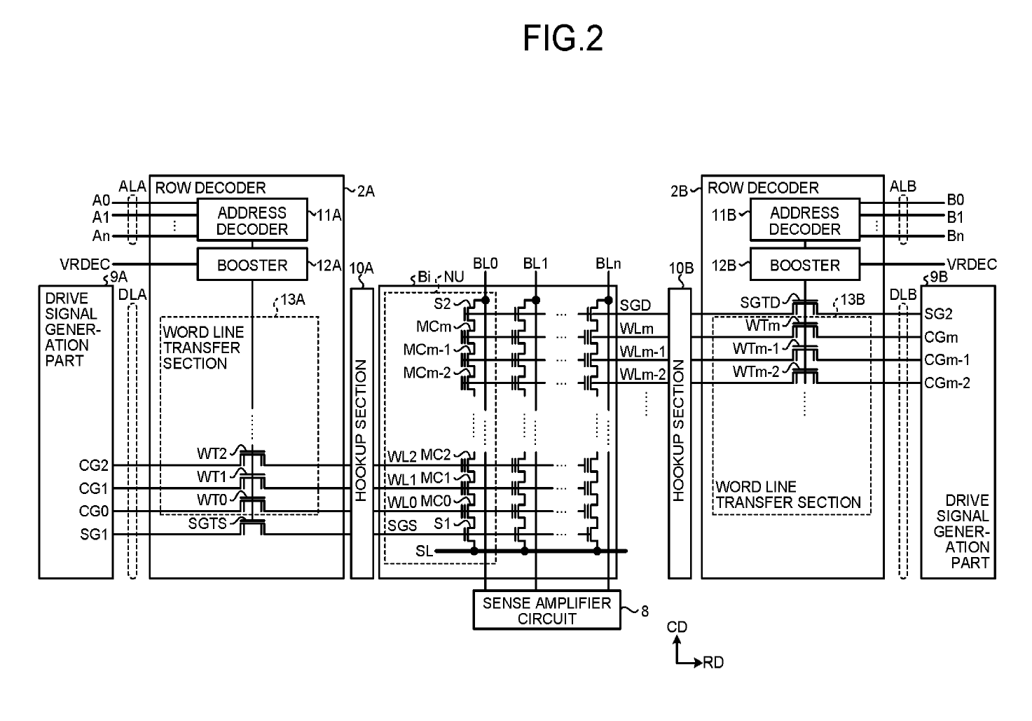

FIG. 2 is a circuit diagram showing a schematic configuration of a block and row decoders arranged in the nonvolatile semiconductor memory device according to the first embodiment.

As shown in FIG. 2, each of the blocks B1 to Bk includes an “m+1”-number (“m” is an integer of 0 or more) of word lines WL0 to WLm, selection gate lines SGD and SGS, and a source line SL. Further, each of the blocks B1 to Bk includes an “n+1”-number (“n” is an integer of 0 or more) of bit lines BL0 to BLn, which are arranged in common to these blocks.

Besides, each of the blocks B1 to Bk includes an “n+1”-number of NAND cells NU, such that the NAND cells NU are respectively connected to the bit lines BL0 to BLn.

Here, each of the NAND cells NU includes cell transistors MC0 to MCm and selection transistors S1 and S2. Each of the memory cells of the memory cell array 1 may be composed of one cell transistor. Further, the cell transistors MC0 to MCm are connected in series to form a NAND string, and the selection transistors S1 and S2 are respectively connected to the opposite ends of the NAND string to form each of the NAND cells NU.

Besides, in each of the NAND cells NU, the control gate electrodes of the cell transistors MC0 to MCm are respectively connected to the word lines WL0 to WLm. A plurality of memory cells that share each of the word lines WL0 to WLm in the row direction defines a page. Further, in each of the NAND cells NU, one end of the NAND string formed of the cell transistors MC0 to MCm is connected to the corresponding one of the bit lines BL0 to BLn via the selection transistor S2, and the other end of the NAND string is connected to the source line SL via the selection transistor S1. The gate electrode of the selection transistor S1 is connected to the selection gate line SGS, and the gate electrode of the selection transistor S2 is connected to the selection gate line SGD.

Here, a hookup section 10A is provided on the left side of the block Bi, and it connects the word lines WL0, WL1, . . . and the selection gate line SGS to the row decoder 2A. A hookup section 10B is provided on the right side of the block Bi, and it connects the word lines WLm, WLm−1, . . . and the selection gate line SGD to the row decoder 2B.

The row decoder 2A includes an address decoder 11A, a booster 12A, a word line transfer section 13A, and a selection gate line transfer transistor SGTS. The control circuit 7 includes a drive signal generation part 9A. The row decoder 2A may be provided for every one of the blocks B1 to Bk, and the drive signal generation part 9A may be shared by the blocks B1 to Bk. The address decoder 11A is equipped with address lines A0 to An, so that a row address ALA is input via the address lines A0 to An. Then, it performs selection of the blocks B1 to Bk in accordance with the designation of the row address ALA. The booster 12A receives an input of a boost voltage VRDEC, and supplies the boost voltage VRDEC to the one of the blocks B1 to Bk selected by the address decoder 11A. The word line transfer section 13A includes word line transfer transistors WT0, WT1, . . . . The word line transfer transistors WT0, WT1, . . . serve to respectively transfer voltages, which are to be applied to the cell transistors MC0, MC1, . . . , to the word lines WL0, WL1, . . . . The selection gate line transfer transistor SGTS serves to transfer a voltage, which is to be applied to the selection transistor S1, to the selection gate line SGS. The gates of the word line transfer transistors WT0, WT1, . . . and the selection gate line transfer transistor SGTS receive an input of an output voltage of the booster 12A. The sources of the word line transfer transistors WT0, WT1, . . . are respectively connected to the word lines WL0, WL1, . . . . The source of the selection gate line transfer transistor SGTS is connected to the selection gate line SGS. The drains of the word line transfer transistors WT0, WT1, . . . are respectively connected to drive signal lines CG0, CG1, . . . . The drain of the selection gate line transfer transistor SGTS is connected to a drive signal line SG1. The drive signal generation part 9A is equipped with the drive signal lines SG1, CG0, CG1, . . . .

The row decoder 2B includes an address decoder 11B, a booster 12B, a word line transfer section 13B, and a selection gate line transfer transistor SGTD. The control circuit 7 includes a drive signal generation part 9B. The row decoder 2B may be provided for every one of the blocks B1 to Bk, and the drive signal generation part 9B may be shared by the blocks B1 to Bk. The address decoder 11B is equipped with address lines B0 to Bn, so that a row address ALB is input via the address lines B0 to Bn. Then, it performs selection of the blocks B1 to Bk in accordance with the designation of the row address ALB. The booster 12B receives an input of a boost voltage VRDEC, and supplies the boost voltage VRDEC to the one of the blocks B1 to Bk selected by the address decoder 11B. The word line transfer section 13B includes word line transfer transistors WTm, WTm−1, . . . . The word line transfer transistors WTm, WTm−1, . . . serve to respectively transfer voltages, which are to be applied to the cell transistors MCm, MCm−1, . . . , to the word lines WLm, WLm−1, . . . . The selection gate line transfer transistor SGTD serves to transfer a voltage, which is to be applied to the selection transistor S2, to the selection gate line SGD. The gates of the word line transfer transistors WTm, WTm−1, . . . and the selection gate line transfer transistor SGTD receive an input of an output voltage of the booster 12B. The sources of the word line transfer transistors WTm, WTm−1, . . . are respectively connected to the word lines WLm, WLm−1, . . . . The source of the selection gate line transfer transistor SGTD is connected to the selection gate line SGD. The drains of the word line transfer transistors WTm, WTm−1, . . . are respectively connected to drive signal lines CGm, CGm−1, . . . . The drain of the selection gate line transfer transistor SGTD is connected to a drive signal line SG2. The drive signal generation part 9B is equipped with the drive signal lines SG2, CGm, CGm−1, . . . .

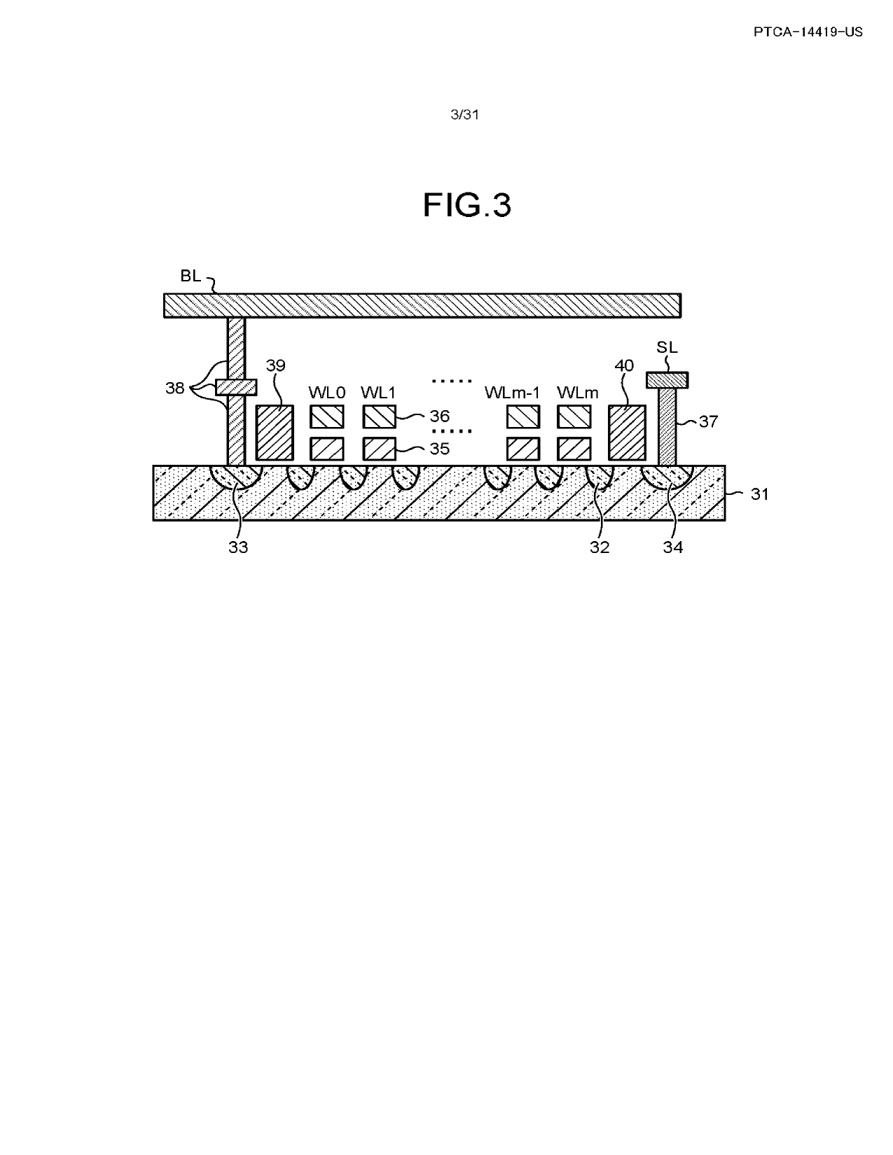

FIG. 3 is a sectional view showing a schematic configuration of one NAND cell of the nonvolatile semiconductor memory device shown in FIG. 1.

As shown in FIG. 3, charge accumulation layers 35 and selection gate electrodes 39 and 40 are provided via a gate insulating film on a well 31. Control gate electrodes 36 are respectively provided via inter-electrode insulating films on the charge accumulation layers 35. In the case of a planar NAND flash memory, floating gates may be used as the charge accumulation layers 35. The gate insulating film mentioned above may have a film thickness set at about 1 to 10 nm.

Further, in the well 31, impurity diffusion layers 32 are formed between the charge accumulation layers 35 and between the charge accumulation layers 35 and the selection gate electrodes 39 and 40, and impurity diffusion layers 33 and 34 are formed between the selection gate electrodes 39 and 40 of adjacent NAND cells. For example, it may be designed such that the well 31 is of the P-type, and the impurity diffusion layers 32, 33, and 34 are of the N-type.

Besides, the impurity diffusion layer 33 is connected via a connection conductor 38 to a bit line BL, and the impurity diffusion layer 34 is connected via a connection conductor 37 to a source line SL. The control gate electrodes 36 of the memory cells are respectively connected to the word lines WL0 to WLm, and the selection gate electrodes 39 and 40 are respectively connected to the selection gate lines SGD and SGS.

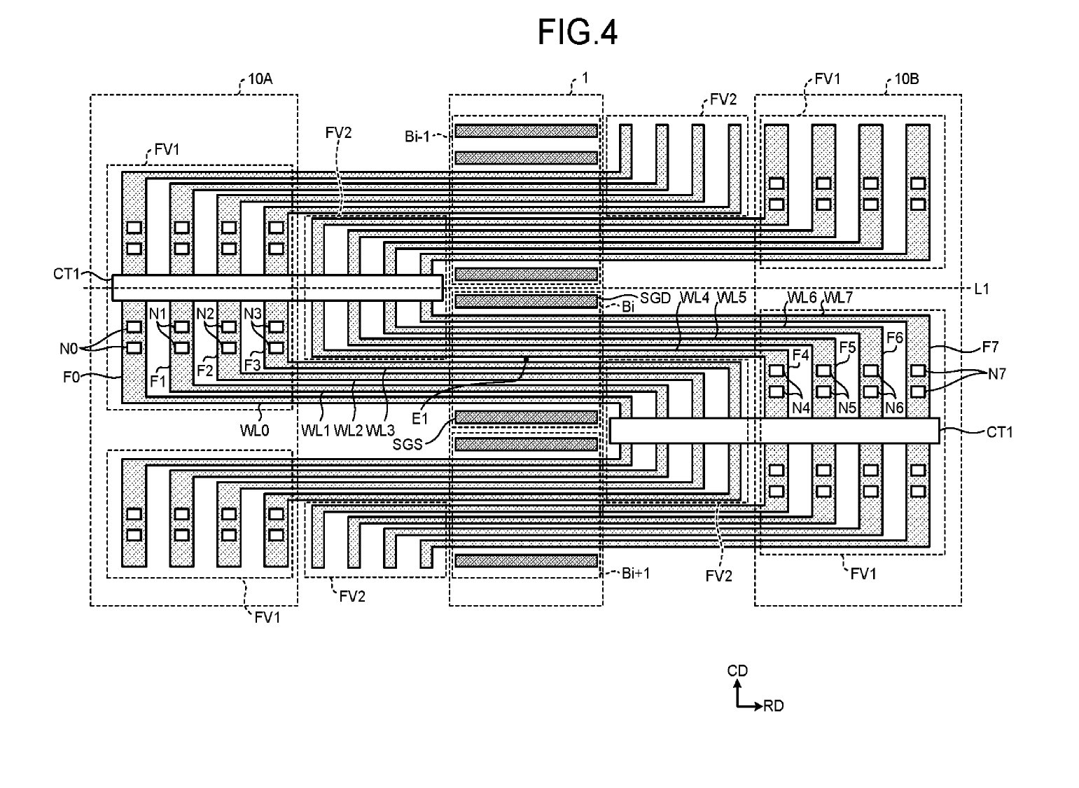

FIG. 4 is a plan view showing a layout configuration of word lines in blocks and hookup sections for three blocks in the nonvolatile semiconductor memory device according to the first embodiment. FIG. 4 shows a configuration example where each of the blocks Bi−1 to Bi+1 is equipped with eight word lines WL0 to WL7. Further, the word lines WL0 to WL7 of the configuration shown here are arranged such that the word lines WL0 to WL3 are connected to the row decoder 2A and the word lines WL4 to WL7 are connected to the row decoder 2B.

As shown in FIG. 4, the hookup section 10A is formed with flag-like portions (flag-shaped portions or word line led out portions) F0 to F3 respectively led out from the word lines WL0 to WL3. The flag-like portions F0 to F3 include contacts N0 to N3 respectively connecting the word lines WL0 to WL3 to the row decoder 2A. The hookup section 10B is formed with flag-like portions F4 to F7 respectively led out from the word lines WL4 to WL7. The flag-like portions F4 to F7 include contacts N4 to N7 respectively connecting the word lines WL4 to WL7 to the row decoder 2B. Here, on one side of the block Bi in the row direction RD (on the left side of the block Bi in FIG. 4), the flag-like portions F0 to F3 of the word lines WL0 to WL3 are arranged at positions more distant from the block Bi as compared with those end portions of the word lines WL4 to WL7 which include no flag-like portions F4 to F7. On the other side of the block Bi in the row direction RD (on the right side of the block Bi in FIG. 4), the flag-like portions F4 to F7 of the word lines WL4 to WL7 are arranged at positions more distant from the block Bi as compared with those end portions of the word lines WL0 to WL3 which include no flag-like portions F0 to F3. For example, the word lines WL0 to WL7 may be formed with a bent part FV1 including the flag-like portions F0 to F7 and a bent part FV2 including no flag-like portions F0 to F7. Further, the bent part FV1 including the flag-like portions F0 to F7 and the bent part FV2 including no flag-like portions F0 to F7 may be led out (and bent) in directions opposite to each other and arranged on the opposite sides of the block Bi. The bent part FV2 including no flag-like portions F0 to F7 may be arranged on the inner side than the bent part FV1 including the flag-like portions F0 to F7, relative to the blocks Bi−1 to Bi+1. Further, the bent parts FV1 and FV2 of the word lines WL0 to WL7 may be provided with a cut part CT1 to cut the word lines WL0 to WL7 for every one of the blocks Bi−1 to Bi+1. At this time, the flag-like portions F0 to F7 for the block Bi may be arranged on the opposite sides of the block Bi such that they are in point symmetry relative to the center E1 of the block Bi. Further, the flag-like portions F0 to F7 for the block Bi and the flag-like portions F0 to F7 for the block Bi−1 adjacent to the block Bi may be arranged in line symmetry relative to the boundary L1 between them. In this respect, however, it is acceptable that a symmetry of the flag-like portions F0 to F7 is collapsed because the position of the cut part CT1 varies and/or the sizes of the selection gate lines SGD and SGS differ from each other.

The line width of the flag-like portions F0 to F7 may be set larger than the line width of the word lines WL0 to WL7. For example, the line width of the word lines WL0 to WL7 may be set at a value smaller than the resolution limit of exposure light, and the line width of the flag-like portions F0 to F7 may be set at a value not smaller than the resolution limit of the exposure light. Further, the line width of the word lines WL0 to WL7 at the bent part FV2 may be set almost equal to the line width of the word lines WL0 to WL7 in the blocks Bi−1 and Bi.

Here, the bent part FV1 including the flag-like portions F0 to F7 and the bent part FV2 including no flag-like portions F0 to F7 are led out in directions opposite to each other and arranged on the opposite sides of the block Bi. With this arrangement, the line width of the word lines WL0 to WL7 at the bent part FV2 can be thinner to reduce the layout area, as compared with a configuration where the bent part FV2 includes the flag-like portions F0 to F7.

Further, the bent part FV2 including no flag-like portions F0 to F7 is arranged on the inner side than the bent part FV1 including the flag-like portions F0 to F7, relative to the blocks Bi−1 to Bi+1. With this arrangement, the space of the flag-like portions F0 to F7 can be expanded in the column direction CD to enlarge the area of the contacts N0 to N7, as compared with a case where the bent part FV1 including the flag-like portions F0 to F7 is arranged on the inner side than the bent part FV2 including no flag-like portions F0 to F7, relative to the blocks Bi−1 to Bi+1.

In the configuration example shown in FIG. 4, the word lines WL0 to WL7 are formed with the bent part FV2, but the bent part FV2 may be omitted to shift the flag-like portions F0 to F7 toward the blocks Bi−1, Bi, and Bi+1 by that much.

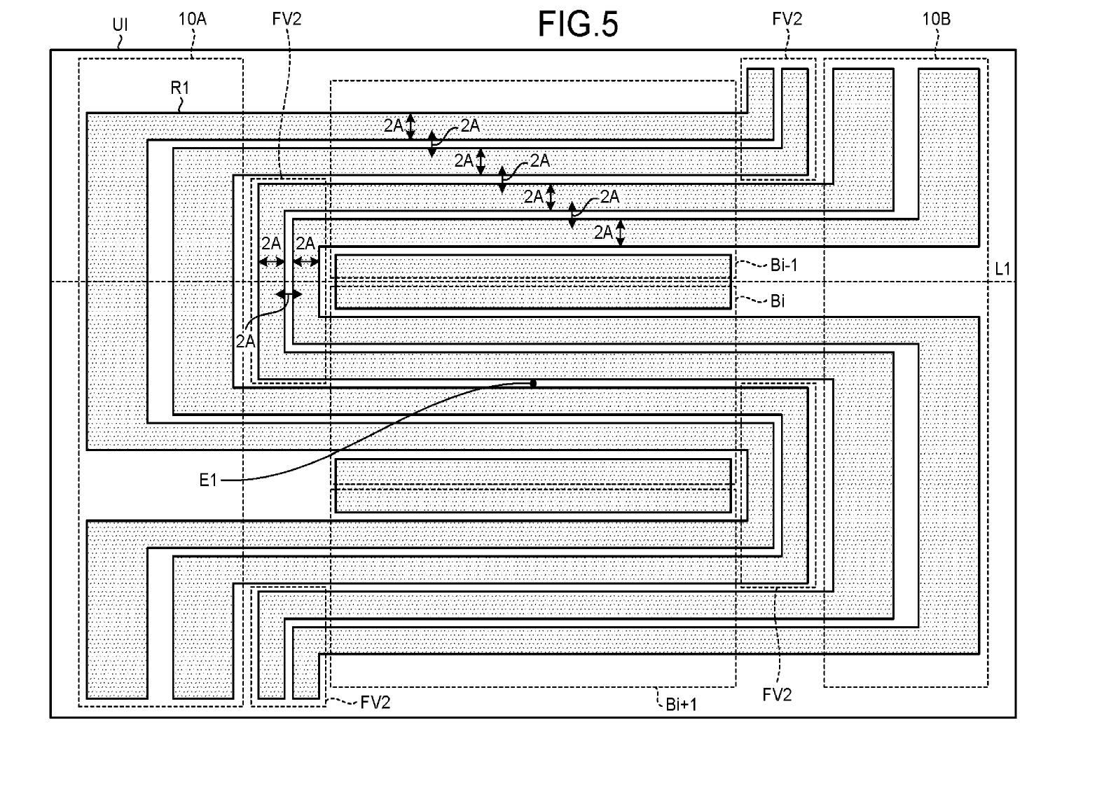

FIGS. 5 to 12 are plan views showing a method of manufacturing the nonvolatile semiconductor memory device according to the first embodiment. FIGS. 5 to 12 show an example about a method of forming the word lines WL0 to WL7 by use of a sidewall transfer technique.

As shown in FIG. 5, a core material pattern R1 is formed on a process target film UI. For example, the process target film UI is formed of a polycrystalline silicon film, which is generally used for word lines or the like. The core material pattern R1 may be made of a resist material, or it may be made of a hard mask material, such as a BSG film or silicon nitride film. At this time, for example, the line width of the portions of the core material pattern R1 corresponding to the word lines WL0 to WL7 in the blocks Bi−1 to Bi+1 may be set at 2A. Here, the portions of the core material pattern R1 corresponding to the flag-like portions F0 to F7 for the block Bi may be arranged on the opposite sides of the block Bi such that they are in point symmetry relative to the center E1 of the block Bi. Further, the portions of the core material pattern R1 corresponding to the flag-like portions F0 to F7 for the block Bi and the flag-like portions F0 to F7 for the block Bi−1 adjacent to the block Bi may be arranged in line symmetry relative to the boundary L1 between them. At this time, the portions of the core material pattern R1 corresponding to the word lines WL0 to WL7 may be formed such that they are continuously bent to the right and left sides alternately for the respective blocks Bi−1 to Bi+1. The line width of the portions of the core material pattern R1 corresponding to the bent part FV2 of the word lines WL0 to WL7 may be set smaller than the line width of the portions of the core material pattern R1 corresponding to the bent part FV1 of the word lines WL0 to WL7. At this time, the line width of the portions of the core material pattern R1 corresponding to the bent part FV2 of the word lines WL0 to WL7 may be set almost equal to the line width of the portions of the core material pattern R1 corresponding to the blocks Bi−1 to Bi+1.

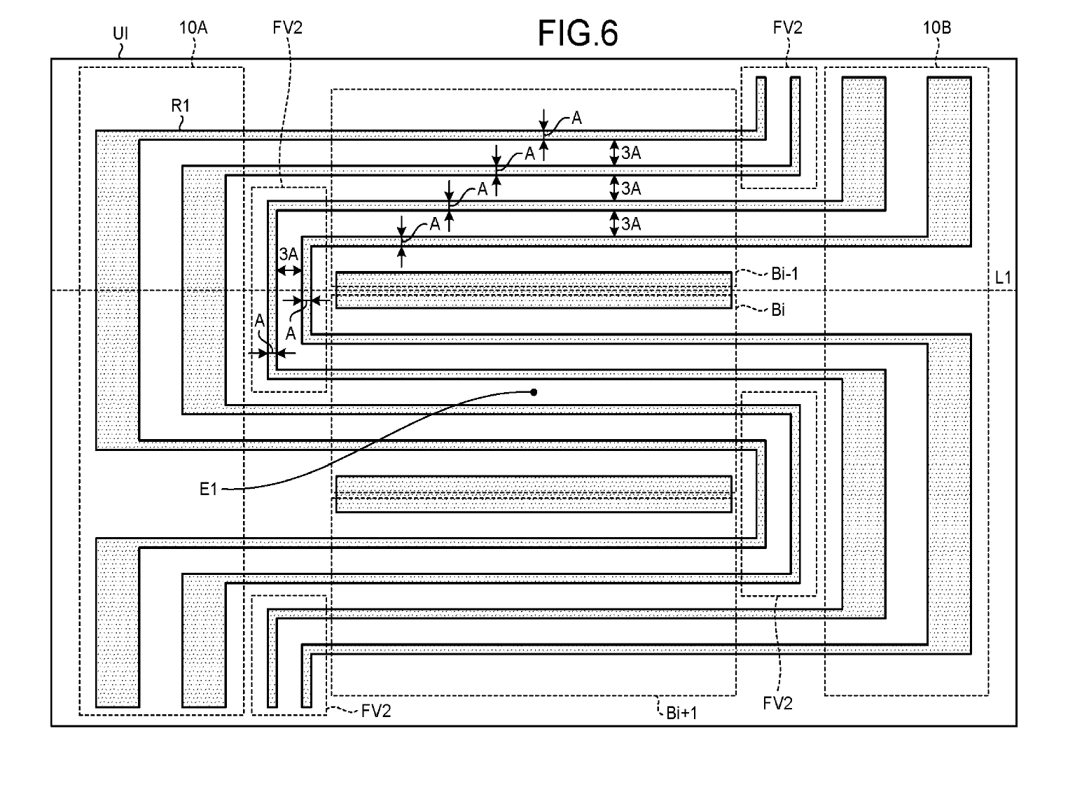

Then, as shown in FIG. 6, slimming of the core material pattern R1 is performed by use of, e.g., an isotropic etching method to reduce the line width of the core material pattern R1. At this time, for example, the line width of the portions of the core material pattern R1 corresponding to the word lines WL0 to WL7 in the blocks Bi−1 to Bi+1 may be set at A, and their intervals may be set at 3A.

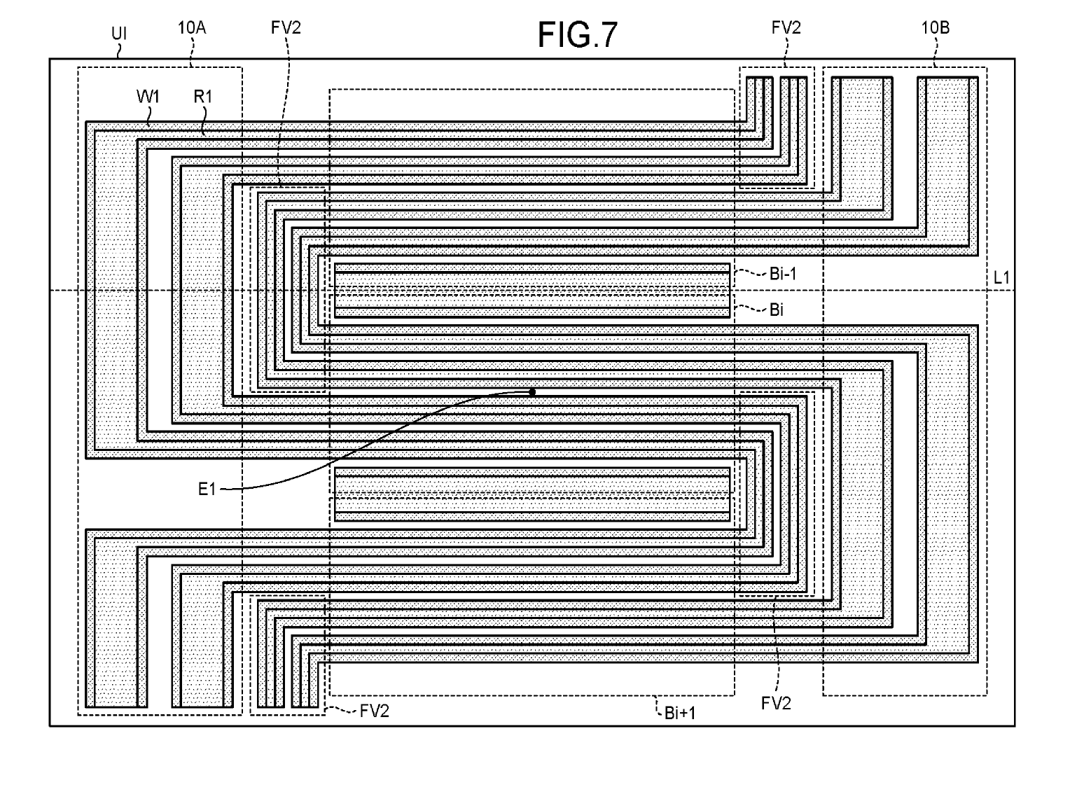

Then, as shown in FIG. 7, a sidewall material high in selectivity relative to the core material pattern R1 is deposited all over on the process target film UI including the sidewall of the core material pattern R1, by use of, e.g., a CVD method. For example, when the core material pattern R1 is formed of a BSG film, a silicon nitride film may be used as the sidewall material high in selectivity relative to the core material pattern R1. Then, the sidewall material is etched by anisotropic etching, so that the process target film UI is exposed and the sidewall material is still left on the sidewall of the core material pattern R1. At this time, a sidewall pattern W1 is formed along the outer periphery of the core material pattern R1. At this time, the line width of the sidewall pattern W1 may be set at A.

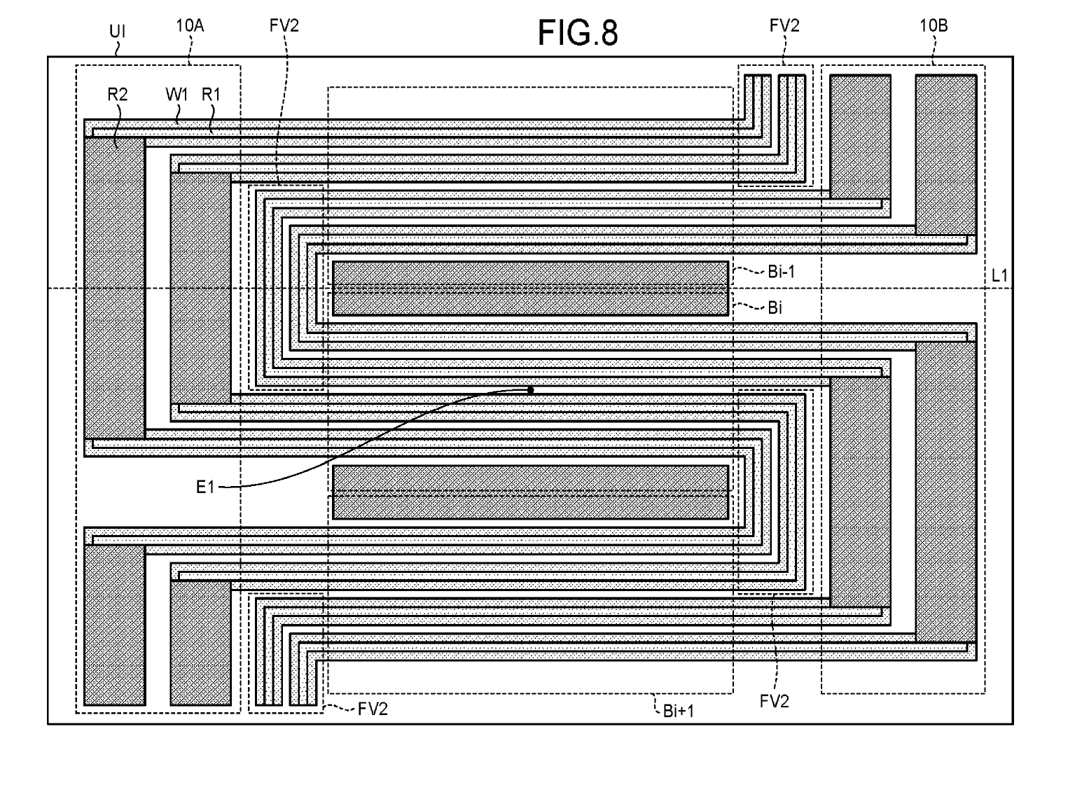

Then, as shown in FIG. 8, a resist film R2 is formed by use of a photo-lithography technique to cover the portions of the core material pattern R1 corresponding to the flag-like portions F0 to F7 of the word lines WL0 to WL7. At this time, the portions of the core material pattern R1 corresponding to the selection gate lines SGD and SGS can also be covered with the resist film R2.

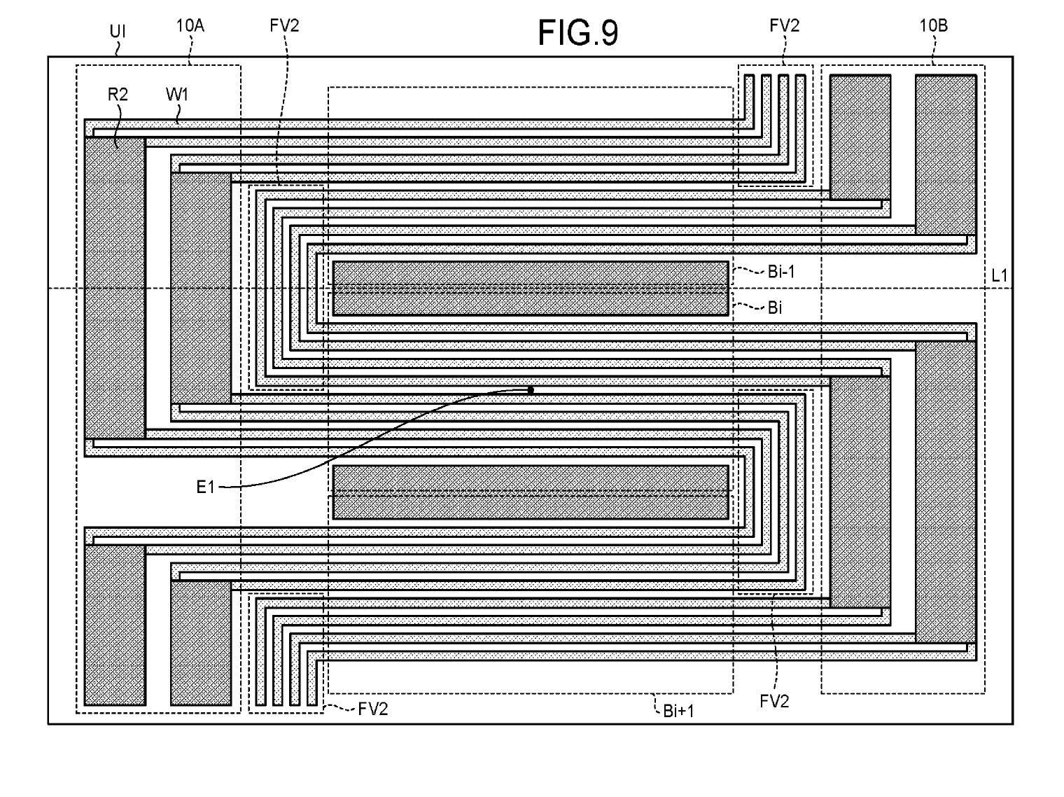

Then, as shown in FIG. 9, part of the core material pattern R1 on the process target film UI is removed by use of an etching technique, such that the sidewall pattern W1 is still left on the process target film UI.

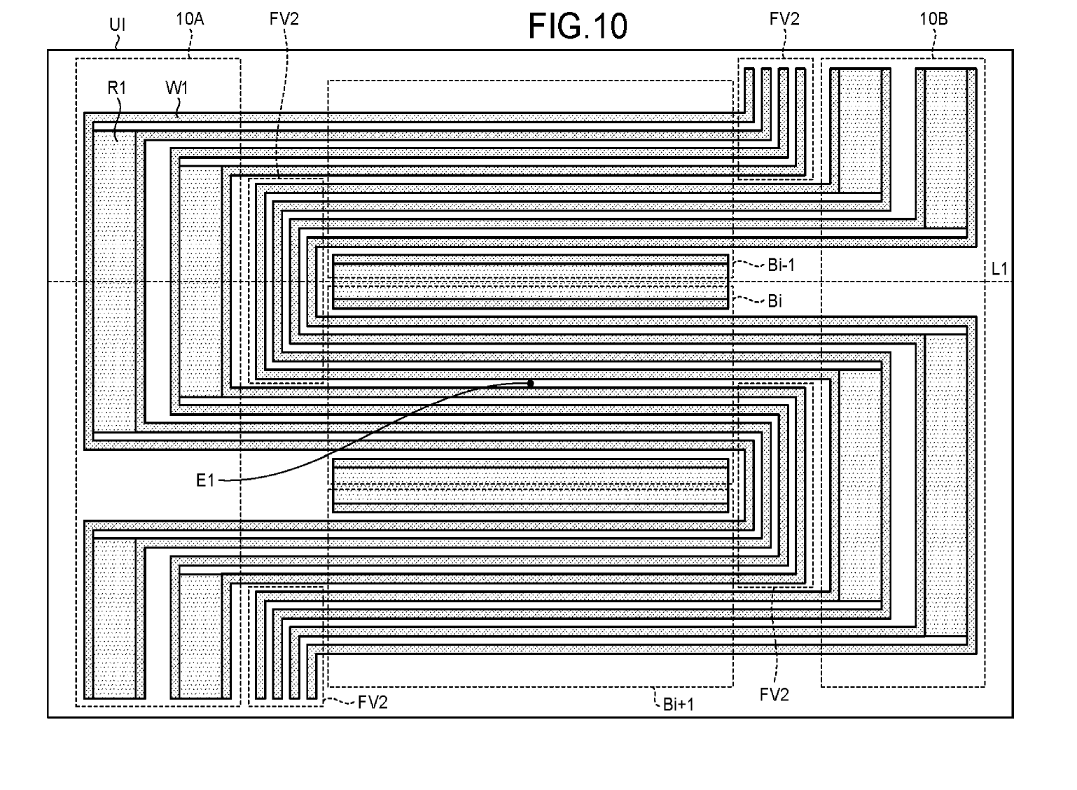

Then, as shown in FIG. 10, the resist film R2 is removed, so that the portions of the core material pattern R1 corresponding to the flag-like portions F0 to F7 of the word lines WL0 to WL7 are exposed. At this time, the portions of the core material pattern R1 corresponding to the selection gate lines SGD and SGS can also be exposed.

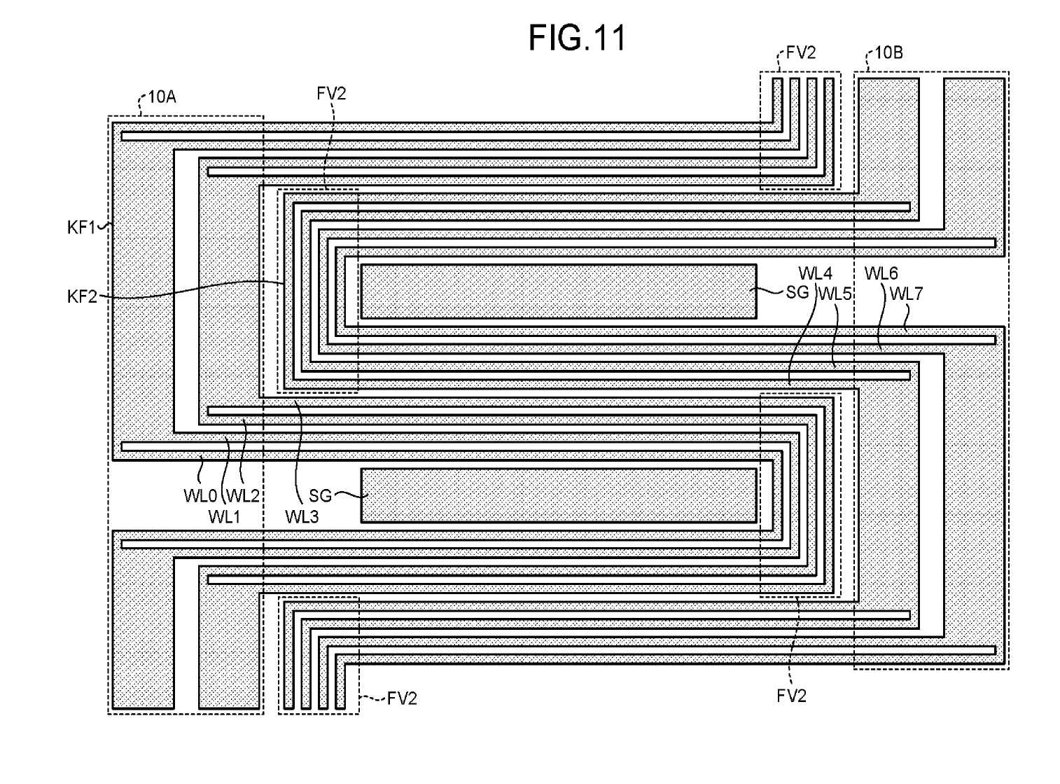

Then, as shown in FIG. 11, while the sidewall pattern W1, the portions of the core material pattern R1 corresponding to the flag-like portions F0 to F7 of the word lines WL0 to WL7, and the portions of the core material pattern R1 corresponding to the selection gate lines SGD and SGS are used as a mask, the process target film UI is processed to form the word lines WL0 to WL7, selection gate lines SG, and bent parts KF1 and KF2.

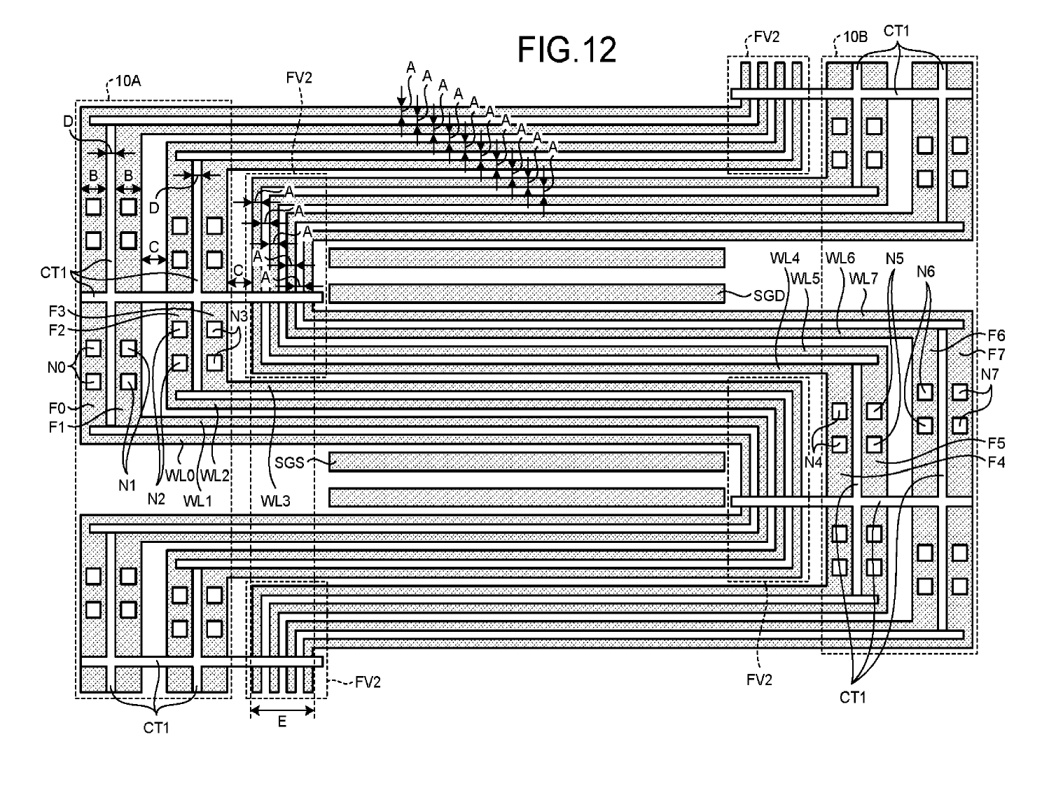

Then, as shown in FIG. 12, the bent parts KF1 and KF2 are cut by the cut part CT1 to cut the word lines WL0 to WL7 for every one of the blocks Bi−1 to Bi+1, and to cut the bent part KF1 into the flag-like portions F0 to F7. Further, each of the selection gate lines SG is cut into the selection gate lines SGD and SGS. Then, the contacts N0 to N7 are respectively formed in the flag-like portions F0 to F7.

Here, for the word lines WL0 to WL7 in the blocks Bi−1 and Bi and the bent part FV2 of the word lines WL0 to WL7, the line width and the intervals may be set at A. The line width of the flag-like portions F0 to F7 may be set at B. The intervals of the flag-like portions F0 to F7 may be set at C. The loop cut width of the flag-like portions F0 to F7 may be set at D.

In this case, for example, if a NAND memory includes 128 word lines per each block, and when the bent part FV2 is equipped with the flag-like portions F0 to F7, the row direction width of each of the bent parts FV1 and FV2 of the word lines WL0 to WL7 is expressed by [{(C+D)/2+B}×64]. On the other hand, when the bent part FV2 is not equipped with the flag-like portions F0 to F7, the width E of the bent part FV2 can be reduced down to 2A×64, and so the reduction effect is expressed by [{(C+D)/2+B}×64]−2A×64.

### Second Embodiment

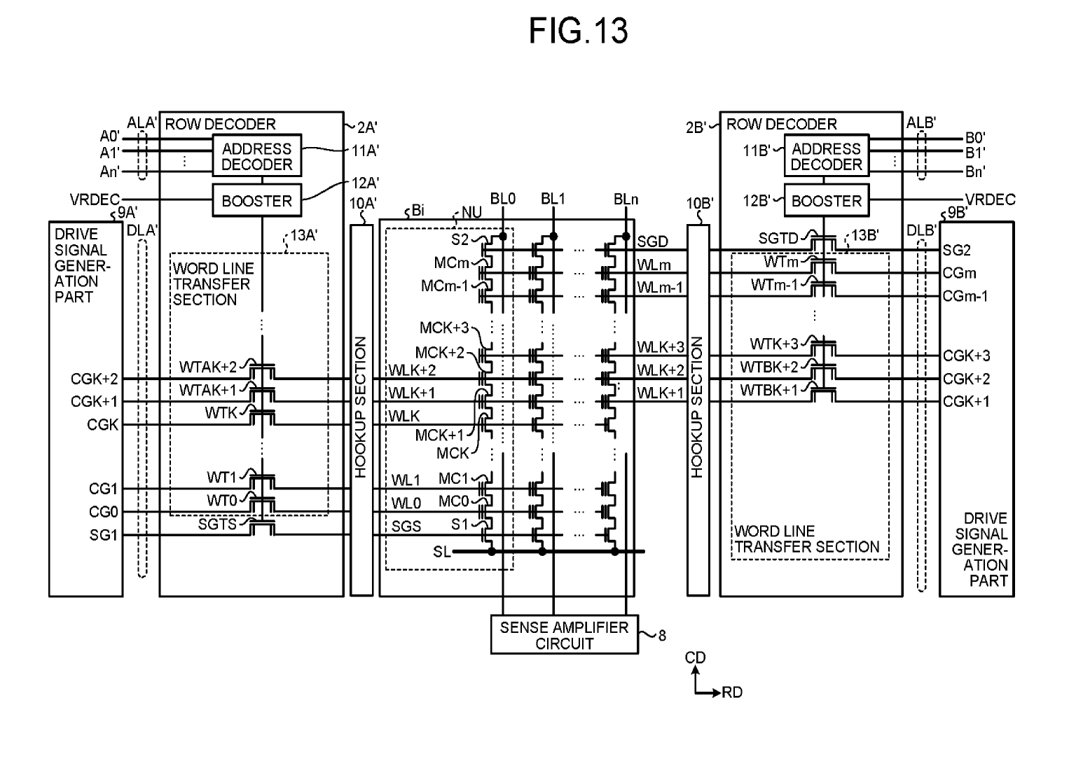

FIG. 13 is a circuit diagram showing a schematic configuration of a block and row decoders arranged in a nonvolatile semiconductor memory device according to a second embodiment.

As shown in FIG. 13, this configuration includes row decoders 2A′ and 2B′, drive signal generation parts 9A′ and 9B′, and hookup sections 10A′ and 10B′, in place of the row decoders 2A and 2B, the drive signal generation parts 9A and 9B, and the hookup sections 10A and 10B shown in FIG. 2. The hookup section 10A′ serves to connect the word lines WL0, WL1, . . . , and WLK+2 and the selection gate line SGS to the row decoder 2A′. The hookup section 10B′ serves to connect the word lines WLm, WLm−1, . . . , and WLK+1 and the selection gate line SGD to the row decoder 2B′. In this case, K may be set at an integer larger than 0 and smaller than “m”.

The row decoder 2A′ includes an address decoder 11A′, a booster 12A′, a word line transfer section 13A′, and the selection gate line transfer transistor SGTS. The address decoder 11A′ is equipped with address lines A0′ to An′, so that a row address ALA′ is input via the address lines A0′ to An′. Then, it performs selection of the blocks B1 to Bk in accordance with the designation of the row address ALA′. The booster 12A′ receives an input of a boost voltage VRDEC, and supplies the boost voltage VRDEC to the one of the blocks B1 to Bk selected by the address decoder 11A′. The word line transfer section 13A′ includes word line transfer transistors WT0, W1, . . . , WTK, WTAK+1, and WTAK+2. The word line transfer transistors WT0, WT1, . . . , WTK, WTAK+1, and WTAK+2 serve to respectively transfer voltages, which are to be applied to cell transistors MC0, MC1, . . . , MCK, MCK+1, and MCK+2, to the word lines WL0, WL1, . . . , WLK, WLK+1, and WLK+2. The gates of the word line transfer transistors WT0, WT1, . . . , WTK, WTAK+1, and WTAK+2 and the selection gate line transfer transistor SGTS receive an input of an output voltage of the booster 12A′. The sources of the word line transfer transistors WT0, WT1, . . . , WTK, WTAK+1, and WTAK+2 are respectively connected to the word lines WL0, WL1, . . . , WLK, WLK+1, and WLK+2. The drains of the word line transfer transistors WT0, WT1, . . . , WTK, WTAK+1, and WTAK+2 are respectively connected to drive signal lines CG0, CG1, . . . , CGK, CGK+1, and CGK+2. The drive signal generation part 9A′ is equipped with the drive signal lines SG1, CG0, CG1, . . . , CGK, CGK+1, and CGK+2.

The row decoder 2B′ includes an address decoder 11B′, a booster 12B′, a word line transfer section 13B′, and the selection gate line transfer transistor SGTD. The address decoder 11B′ is equipped with address lines B0′ to Bn′, so that a row address ALB′ is input via the address lines B0′ to Bn′. Then, it performs selection of the blocks B1 to Bk in accordance with the designation of the row address ALB′. The booster 12B′ receives an input of a boost voltage VRDEC, and supplies the boost voltage VRDEC to the one of the blocks B1 to Bk selected by the address decoder 11B′. The word line transfer section 13B′ includes word line transfer transistors WTm, WTm−1, . . . , WTK+3, WTBK+2, and WTBK+1. The word line transfer transistors WTm, WTm−1, . . . , WTK+3, WTBK+2, and WTBK+1 serve to respectively transfer voltages, which are to be applied to cell transistors MCm, MCm−1, . . . , MCK+3, MCK+2, and MCK+1, to the word lines WLm, WLm−1, . . . , WLK+3, WLK+2, and WLK+1. The gates of the word line transfer transistors WTm, WTm−1, . . . , WTK+3, WTBK+2, and WTBK+1 and the selection gate line transfer transistor SGTD receive an input of an output voltage of the booster 12B′. The sources of the word line transfer transistors WTm, WTm−1, . . . , WTK+3, WTBK+2, and WTBK+1 are respectively connected to the word lines WLm, WLm−1, . . . , WLK+3, WLK+2, and WLK+1. The drains of the word line transfer transistors WTm, WTm−1, . . . , WTK+3, WTBK+2, and WTBK+1 are respectively connected to drive signal lines CGm, CGm−1, . . . , CGK+3, CGK+2, and CGK+1. The drive signal generation part 9B′ is equipped with the drive signal lines SG2, CGm, CGm−1, . . . , CGK+3, CGK+2, and CGK+1.

Here, the word lines WLK+2 and WLK+1 can be supplied with voltages from the row decoders 2A′ and 2B′. Accordingly, the word line WLK to be supplied with a voltage from the row decoder 2A′ and the word line WLK+3 to be supplied with a voltage from the row decoder 2B′ can be prevented from being present adjacent to each other, so that the potential difference between the word lines WLK and WLK+3 can be reduced. In this respect, the memory cell MCK+2 and MCK+1 connected to the word lines WLK+2 and WLK+1 may be utilized as dummy cells.

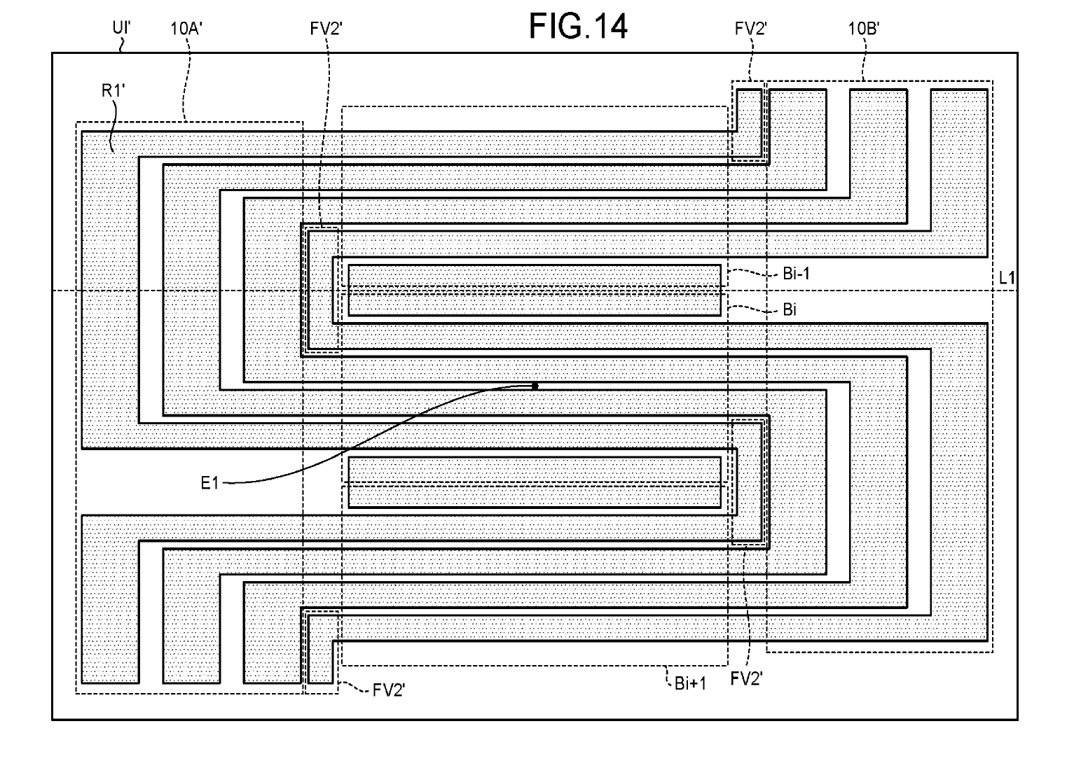

FIGS. 14 to 21 are plan views showing a method of manufacturing the nonvolatile semiconductor memory device according to the second embodiment. FIGS. 14 to 21 show a configuration example where each of the blocks Bi−1 to Bi+1 is equipped with eight word lines WL0 to WL7. Further, the word lines WL0 to WL7 of the configuration shown here are arranged such that the word lines WL0 to WL2 are connected to the row decoder 2A′, the word lines WL5 to WL7 are connected to the row decoder 2B′, and the word lines WL3 and WL4 are connected to the row decoders 2A′ and 2B′.

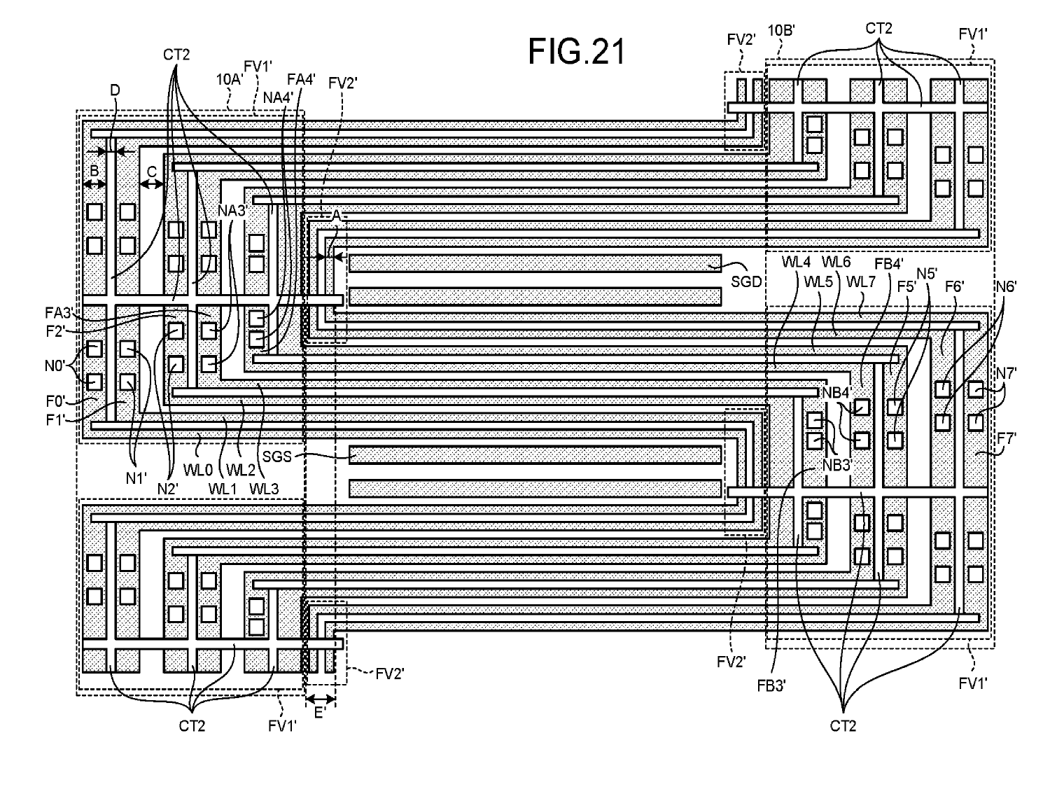

As shown in FIG. 14, a core material pattern R1′ is formed on a process target film UI′. Here, the portions of the core material pattern R1′ corresponding to the flag-like portions F0′ to F2′, FA3′, FA4′, FB3′, FB4′, and F5′ to F7′ for the block Bi shown in FIG. 21 may be arranged on the opposite sides of the block Bi such that they are in point symmetry relative to the center E1 of the block Bi. Further, the portions of the core material pattern R1′ corresponding to the flag-like portions F0′ to F2′, FA3′, FA4′, FB3′, FB4′, and F5′ to F7′ for the block Bi and the flag-like portions F0′ to F2′, FA3′, FA4′, FB3′, FB4′, and F5′ to F7′ for the block Bi−1 adjacent to the block Bi may be arranged in line symmetry relative to the boundary L1 between them. At this time, the portions of the core material pattern R1′ corresponding to the word lines WL0 to WL7 may be formed such that they are continuously bent to the right and left sides alternately for the respective blocks Bi−1 to Bi+1. The line width of the portions of the core material pattern R1′ corresponding to the bent part FV2′ of the word lines WL0 to WL7 may be set smaller than the line width of the portions of the core material pattern R1′ corresponding to the flag-like portions F0′ to F2′, FA3′, FA4′, FB3′, FB4′, and F5′ to F7′ of the word lines WL0 to WL7. At this time, the line width of the portions of the core material pattern R1′ corresponding to the bent part FV2′ of the word lines WL0 to WL7 may be set almost equal to the width of the portions of the core material pattern R1′ corresponding to the blocks Bi−1 to Bi+1.

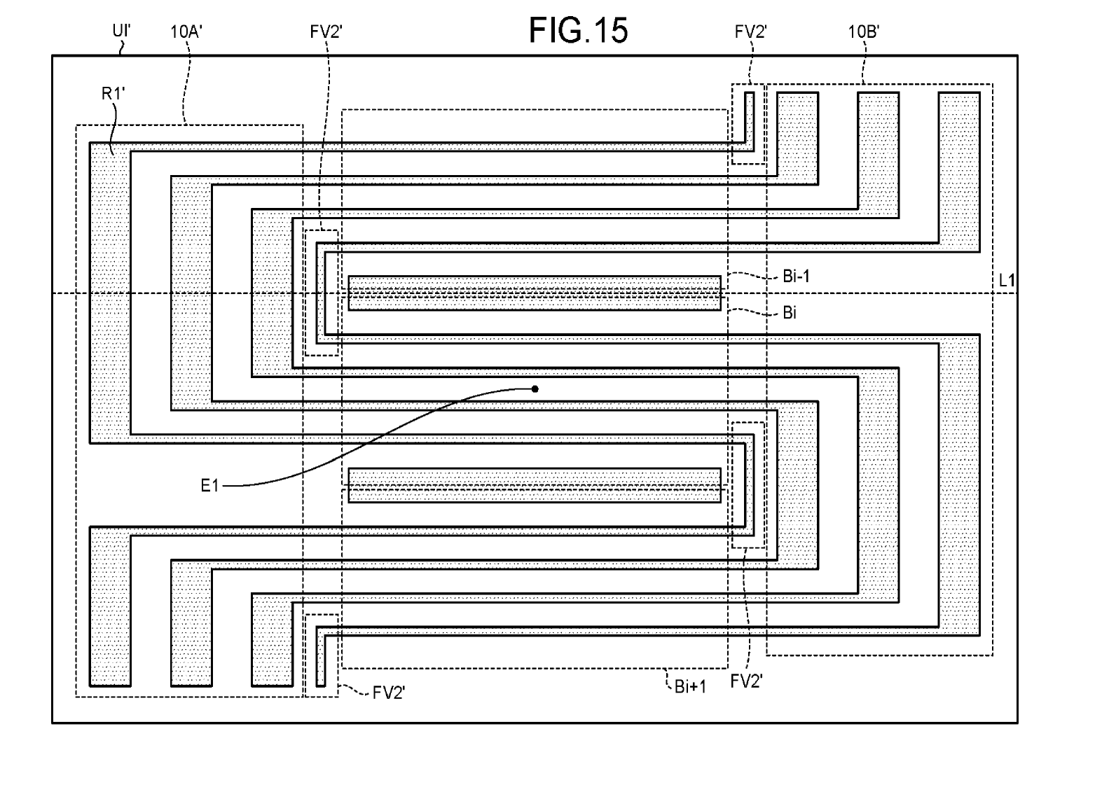

Then, as shown in FIG. 15, slimming of the core material pattern R1′ is performed by use of, e.g., an isotropic etching method to reduce the line width of the core material pattern R1′.

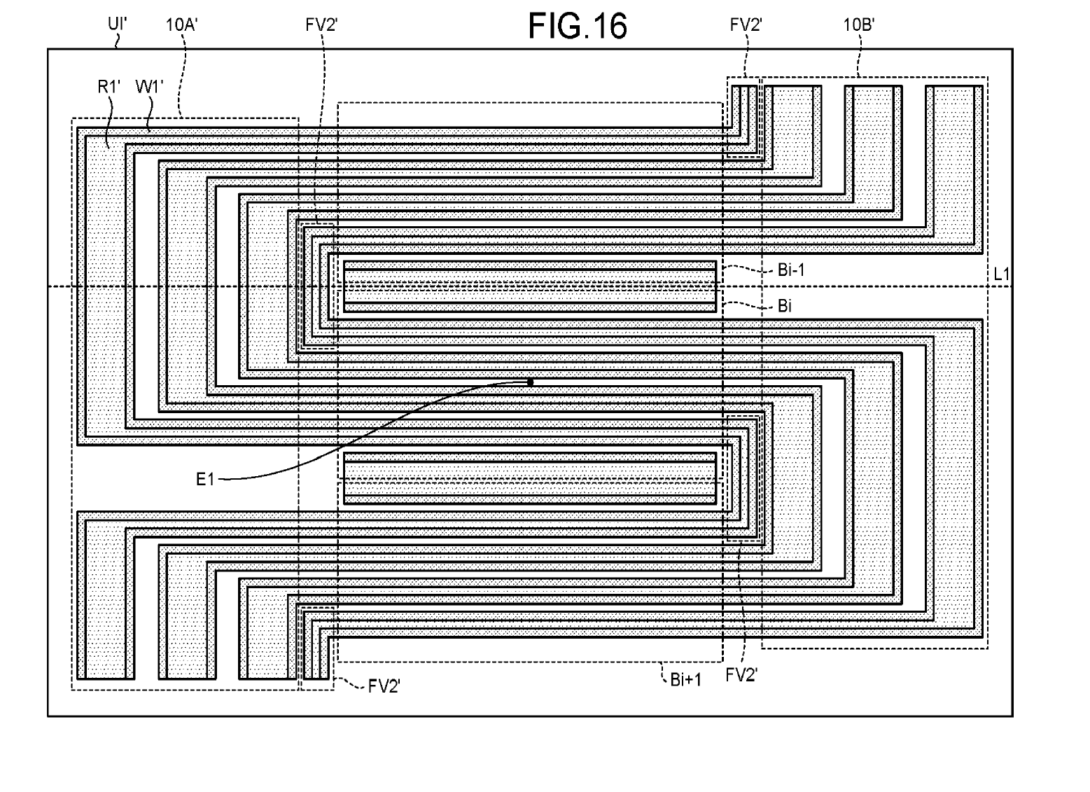

Then, as shown in FIG. 16, a sidewall material high in selectivity relative to the core material pattern R1′ is deposited all over on the process target film UI′ including the sidewall of the core material pattern R1′, by use of, e.g., a CVD method. Then, the sidewall material is etched by anisotropic etching, so that the process target film UI′ is exposed and the sidewall material is still left on the sidewall of the core material pattern R1′. At this time, a sidewall pattern W1′ is formed along the outer periphery of the core material pattern R1′.

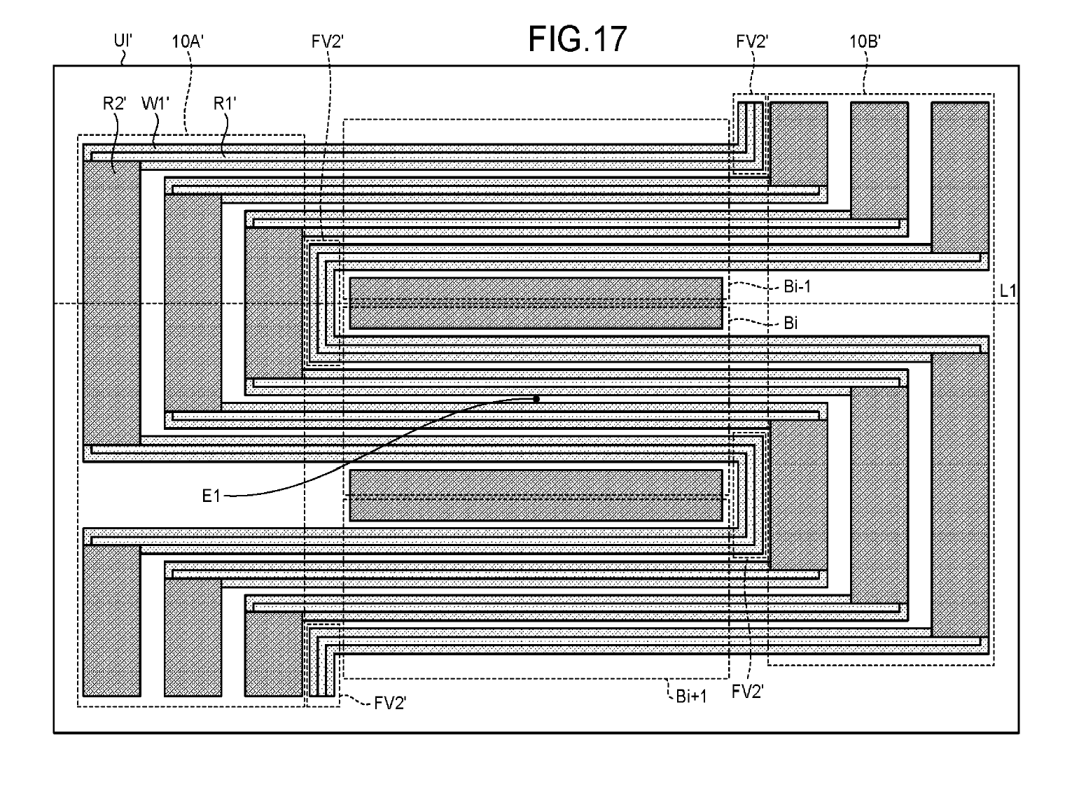

Then, as shown in FIG. 17, a resist film R2′ is formed by use of a photo-lithography technique to cover the portions of the core material pattern R1′ corresponding to the flag-like portions F0′ to F2′, FA3′, FA4′, FB3′, FB4′, and F5′ to F7′ of the word lines WL0 to WL7. At this time, the portions of the core material pattern R1′ corresponding to the selection gate lines SGD and SGS can also be covered with the resist film R2′.

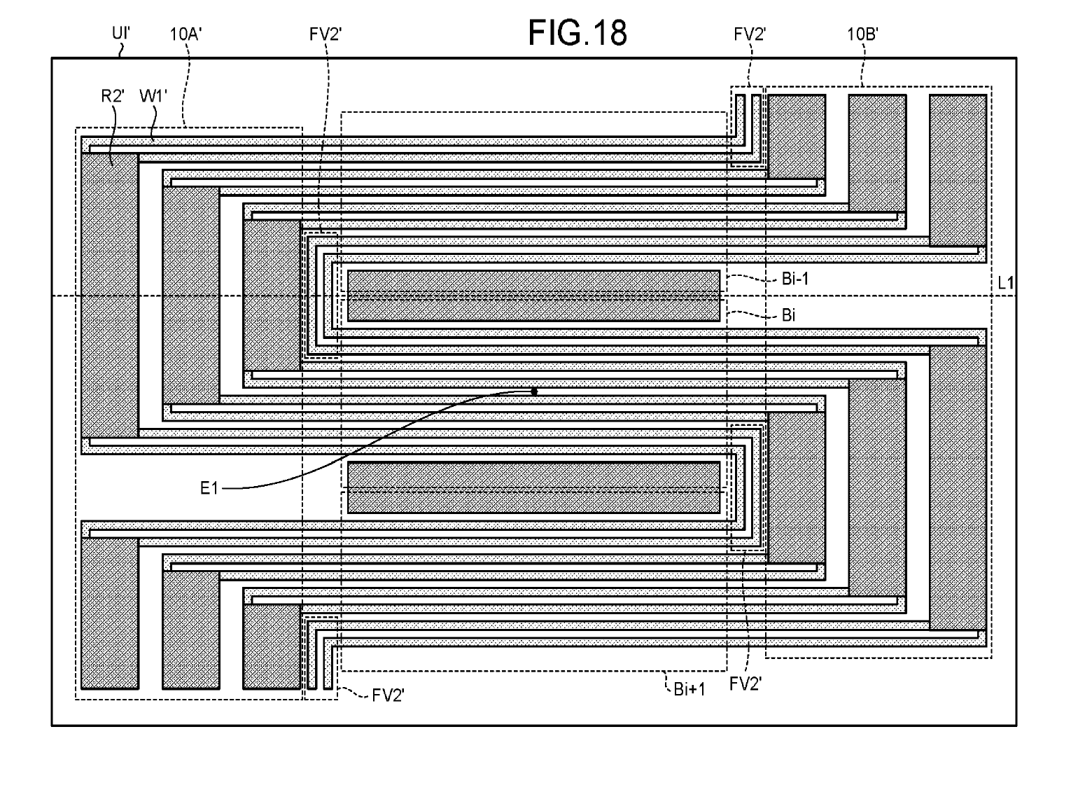

Then, as shown in FIG. 18, part of the core material pattern R1′ on the process target film UI′ is removed by use of an etching technique, such that the sidewall pattern W1′ is still left on the process target film UI′.

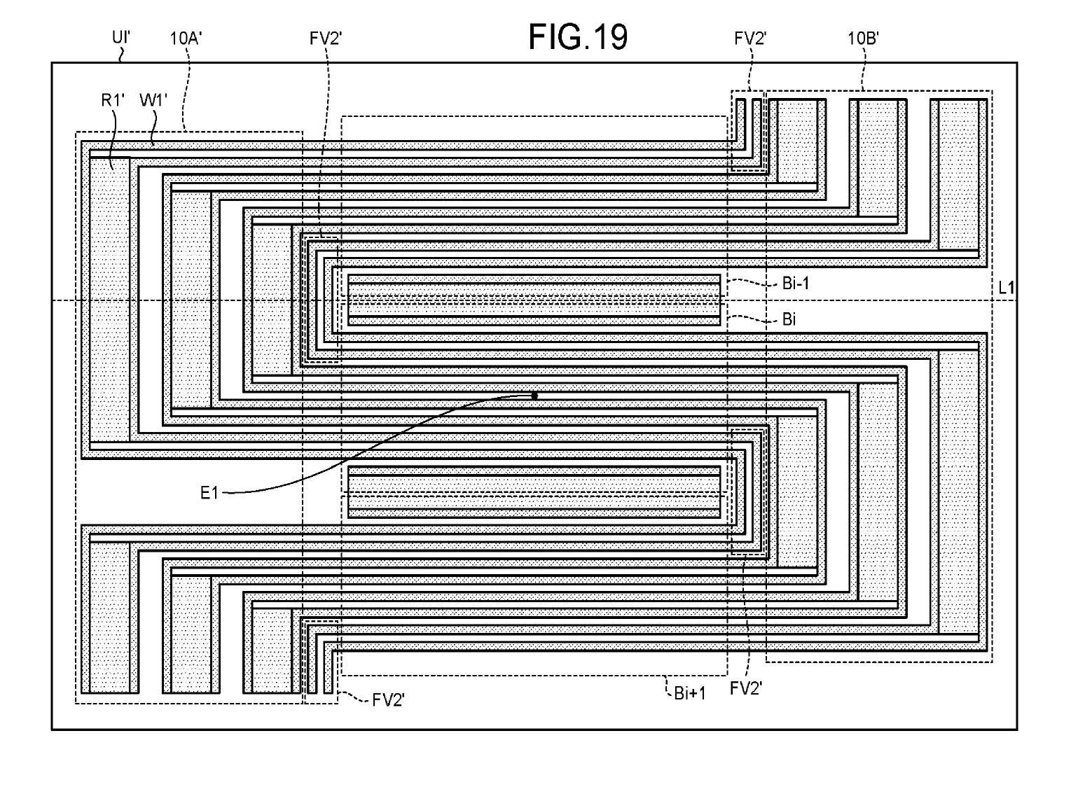

Then, as shown in FIG. 19, the resist film R2′ is removed, so that the portions of the core material pattern R1′ corresponding to the flag-like portions F0′ to F2′, FA3′, FA4′, FB3′, FB4′, and F5′ to F7′ of the word lines WL0 to WL7 are exposed. At this time, the portions of the core material pattern R1′ corresponding to the selection gate lines SGD and SGS can also be exposed.

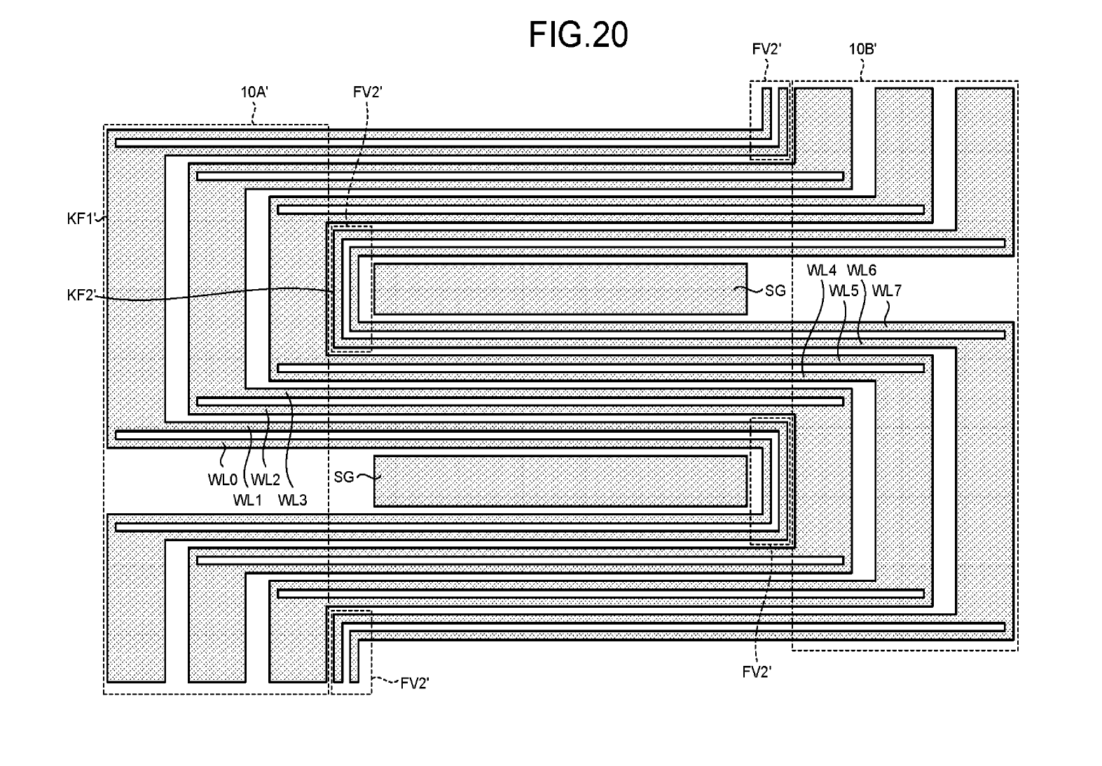

Then, as shown in FIG. 20, while the sidewall pattern W1′, the portions of the core material pattern R1′ corresponding to the flag-like portions F0′ to F2′, FA3′, FA4′, FB3′, FB4′, and F5′ to F7′ of the word lines WL0 to WL7, and the portions of the core material pattern R1′ corresponding to the selection gate lines SGD and SGS are used as a mask, the process target film UI′ is processed to form the word lines WL0 to WL7, selection gate lines SG, and bent parts KF1′ and KF2′.

Then, as shown in FIG. 21, the bent parts KF1′ and KF2′ are cut by a cut part CT2 to cut the word lines WL0 to WL7 for every one of the blocks Bi−1 to Bi+1, and to cut the bent part KF1′ into the flag-like portions F0′ to F2′, FA3′, FA4′, FB3′, FB4′, and F5′ to F7′. Further, each of the selection gate lines SG is cut into the selection gate lines SGD and SGS. Then, the contacts N0′ to N2′, NA3′, NA4′, NB3′, NB4′, and N5′ to N7′ are respectively formed in the flag-like portions F0′ to F2′, FA3′, FA4′, FB3′, FB4′, and F5′ to F7′.

Here, the line width of the word lines WL0 to WL7 in the blocks Bi−1 and Bi and the line width and the intervals at the bent part FV2′ of the word lines WL0 to WL7 may be set at A. The line width of the flag-like portions F0′ to F2′, FA3′, FA4′, FB3′, FB4′, and F5′ to F7′ may be set at B. The intervals of the flag-like portions F0′ to F2′, FA3′, FA4′, FB3′, FB4′, and F5′ to F7′ may be set at C. The loop cut width of the flag-like portions FC′ to F2′, FA3′, FA4′, FB3′, FB4′, and F5′ to F7′ may be set at D. In this configuration where the bent part FV2′ is not equipped with the flag-like portions F0′ to F2′, FA3′, FA4′, FB3′, FB4′, and F5′ to F7′, the width E′ of the bent part FV2′ can be smaller. For example, if a NAND memory includes 128 word lines per each block, the reduction effect in the row direction width of the bent parts FV1′ and FV2′ of the word lines WL0 to WL7 is expressed by [{(C+D)/2+B}×(64+1)]−2A×(64−1).

### Third Embodiment

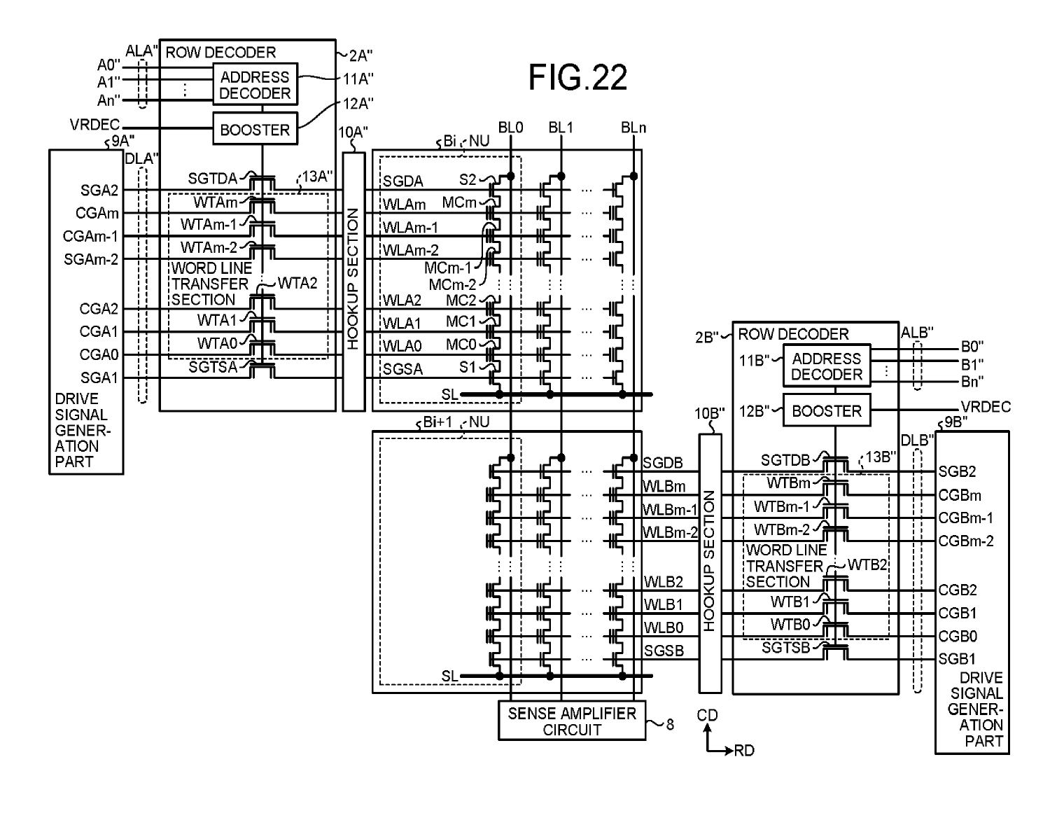

FIG. 22 is a circuit diagram showing a schematic configuration of clocks and row decoders arranged in a nonvolatile semiconductor memory device according to a third embodiment.

As shown in FIG. 22, this configuration includes row decoders 2A″ and 2B″, drive signal generation parts 9A″ and 9B″, and hookup sections 10A″ and 10B″, in place of the row decoders 2A and 2B, the drive signal generation parts 9A and 9B, and the hookup sections 10A and 10B shown in FIG. 2. The hookup section 10A″ serves to connect the word lines WLA0, WLA1, . . . , and WLAm and selection gate lines SGSA and SGDA to the row decoder 2A″. The hookup section 10B″ serves to connect the word lines WLB0, WLB1, . . . , and WLBm and selection gate lines SGSB and SGDB to the row decoder 2B″.

The row decoder 2A″ includes an address decoder 11A″, a booster 12A″, a word line transfer section 13A″, and selection gate line transfer transistors SGTSA and SGTDA. The address decoder 11A″ is equipped with address lines A0″ to An″, so that a row address ALA″ is input via the address lines A0″ to An″. Then, it performs selection of the blocks B1 to Bk in accordance with the designation of the row address ALA″. The booster 12A″ receives an input of a boost voltage VRDEC, and supplies the boost voltage VRDEC to the one of the blocks B1 to Bk selected by the address decoder 11A″. The word line transfer section 13A″ includes word line transfer transistors WTA0, WTA1, . . . , and WTAm. The word line transfer transistors WTA0, WTA1, . . . , and WTAm serve to respectively transfer voltages, which are to be applied to the cell transistors MC0, MC1, . . . , and MCm of the block Bi, to the word lines WLA0, WLA1, . . . , and WLAm. The gates of the word line transfer transistors WTA0, WTA1, . . . , and WTAm and the selection gate line transfer transistors SGTSA and SGTDA receive an input of an output voltage of the booster 12A″. The sources of the word line transfer transistors WTA0, WTA1, . . . , and WTAm are respectively connected to the word lines WLA0, WLA1, . . . , and WLAm. The sources of the selection gate line transfer transistors SGTSA and SGTDA are respectively connected to the selection gate lines SGSA and SGDA. The drains of the word line transfer transistors WTA0, WTA1, . . . , and WTAm are respectively connected to drive signal lines CGA0, CGA1, . . . , and CGAm. The drains of the selection gate line transfer transistors SGTSA and SGTDA are respectively connected to drive signal lines SGA1 and SGA2. The drive signal generation part 9A″ is equipped with the drive signal lines SGA1, SGA2, CGA0, CGA1, . . . , and CGAm.

The row decoder 2B″ includes an address decoder 11B″, a booster 12B″, a word line transfer section 13B″, and selection gate line transfer transistors SGTSB and SGTDB. The address decoder 11B″ is equipped with address lines B0″ to Bn″, so that a row address ALB″ is input via the address lines B0″ to Bn″. Then, it performs selection of the blocks B1 to Bk in accordance with the designation of the row address ALB″. The booster 12B″ receives an input of a boost voltage VRDEC, and supplies the boost voltage VRDEC to the one of the blocks B1 to Bk selected by the address decoder 11B″. The word line transfer section 13B″ includes word line transfer transistors WTB0, WTB1, . . . , and WTBm. The word line transfer transistors WTB0, WTB1, . . . , and WTBm serve to respectively transfer voltages, which are to be applied to the cell transistors MC0, MC1, . . . , and MCm of the block Bi+1, to the word lines WLB0, WLB1, . . . , and WLBm. The gates of the word line transfer transistors WTB0, WTB1, . . . , and WTBm and the selection gate line transfer transistors SGTSB and SGTDB receive an input of an output voltage of the booster 12B″. The sources of the word line transfer transistors WTB0, WTB1, . . . , and WTBm are respectively connected to the word lines WLB0, WLB1, . . . , and WLBm. The sources of the selection gate line transfer transistors SGTSB and SGTDB are respectively connected to the selection gate lines SGSB and SGDB. The drains of the word line transfer transistors WTB0, WTB1, . . . , and WTBm are respectively connected to drive signal lines CGB0, CGB1, . . . , and CGBm. The drains of the selection gate line transfer transistors SGTSB and SGTDB are respectively connected to drive signal lines SGB1 and SGB2. The drive signal generation part 9B″ is equipped with the drive signal lines SGB1, SGB2, CGB0, CGB1, . . . , and CGBm.

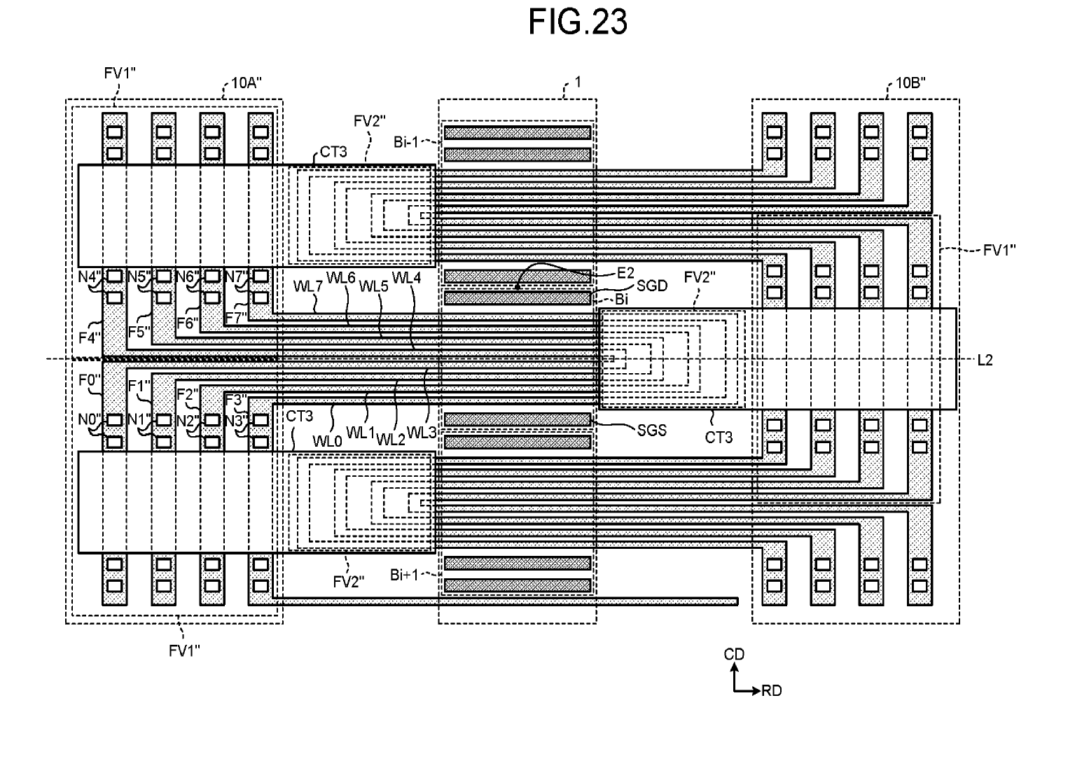

FIG. 23 is a plan view showing a layout configuration of word lines in blocks and hookup sections for three blocks in the nonvolatile semiconductor memory device according to the third embodiment. FIG. 23 shows a configuration example where each of the blocks Bi−1 to Bi+1 is equipped with eight word lines WL0 to WL7. Further, the configuration shown here are arranged such that the word lines WL0 to WL7 of the block Bi are connected to the row decoder 2A″ and the word lines WL0 to WL7 of each of the blocks Bi−1 and Bi+1 are connected to the row decoder 2B″.

As shown in FIG. 23, the hookup section 10A″ is formed with flag-like portions F0″ to F7″ respectively led out from the word lines WL0 to WL7 of the block Bi. The flag-like portions F0″ to F7″ include contacts N0″ to N7″ respectively connecting the word lines WL0 to WL7 of the block Bi to the row decoder 2A″. The hookup section 10B″ is formed with flag-like portions F0″ to F7″ respectively led out from the word lines WL0 to WL7 of each of the blocks Bi−1 and Bi+1. The flag-like portions F0″ to F7″ include contacts N0″ to N7″ respectively connecting the word lines WL0 to WL7 of each of the blocks Bi−1 and Bi+1 to the row decoder 2B″. Here, on one side of the blocks Bi−1, Bi, and Bi+1 in the row direction RD (on the left side of the blocks Bi−1, Bi, and Bi+1 in FIG. 23), the flag-like portions F0″ to F7″ of the word lines WL0 to WL7 of the block Bi are arranged at positions more distant from the blocks Bi−1, Bi, and Bi+1 as compared with those end portions of the word lines WL0 to WL7 of each of the blocks Bi−1 and Bi+1 which include no flag-like portions F0″ to F7″. On the other side of the blocks Bi−1, Bi, and Bi+1 in the row direction RD (on the right side of the blocks Bi−1, Bi, and Bi+1 in FIG. 23), the flag-like portions F0″ to F7″ of the word lines WL0 to WL7 of each of the blocks Bi−1 and Bi+1 are arranged at positions more distant from the blocks Bi−1, Bi, and Bi+1 as compared with those end portions of the word lines WL0 to WL7 of the block Bi which include no flag-like portions F0″ to F7″. For example, the block Bi and the block Bi−1 or Bi+1 may be alternately arranged in the column direction CD, under conditions where the block Bi is configured such that the flag-like portions F0″ to F3″ of the word lines WL0 to WL3 and the flag-like portions F4″ to F7″ of the word lines WL4 to WL7 are led out (and bent) in directions opposite to each other on one side of the block in the row direction RD, and where each of the blocks Bi−1 and Bi+1 is configured such that the flag-like portions F0″ to F3″ of the word lines WL0 to WL3 and the flag-like portions F4″ to F7″ of the word lines WL4 to WL7 are led out (and cent) in directions opposite to each other on the other side of the block in the row direction RD. At this time, the flag-like portions F0″ to F7″ for the block Bi may be arranged on one side of the block Bi such that they are in line symmetry relative to the center line L2 of the block Bi. Further, the flag-like portions F0″ to F7″ for the block Bi and the flag-like portions F0″ to F7″ for the block Bi−1 adjacent to the block Bi may be arranged on the opposite sides of the blocks Bi−1 and Bi such that they are in point symmetry relative to the center E2 between the blocks Bi−1 and Bi. In this respect, however, it is acceptable that a symmetry of the flag-like portions F0″ to F7″ is collapsed because the position of a cut part CT3 varies and/or the sizes of the selection gate lines SGD and SGS differ from each other. The line width of the flag-like portions F0″ to F7″ may be set larger than the line width of the word lines WL0 to WL7. For example, the line width of the word lines WL0 to WL7 may be set at a value smaller than the resolution limit of exposure light, and the line width of the flag-like portions F0″ to F7″ may be set at a value not smaller than the resolution limit of the exposure light.

Here, a bent part FV1″ on the right side of the word lines WL0 to WL7 of each of the blocks Bi−1 and Bi+1 may be formed with the flag-like portions F0″ to F7″, wherein the lines are bent over a distance corresponding to two blocks (the block Bi, a half of the block Bi−1, and a half of the block Bi+1). Further, a bent part FV2″ on the left side of the word lines WL0 to WL7 of each of the blocks Bi−1 and Bi+1 may be formed without the flag-like portions F0″ to F7″, wherein the lines are bent over a distance corresponding to one block (the block Bi−1 or block Bi+1). On the other hand, a bent part FV1″ on the left side of the word lines WL0 to WL7 of the block Bi may be formed with the flag-like portions F0″ to F7″, wherein the lines are bent over a distance corresponding to two blocks (the block Bi−1, a half of the block Bi−2, and a half of the block Bi; or the block Bi+1, a half of the block Bi+2, and a half of the block Bi). Further, a bent part FV2″ on the right side of the word lines WL0 to WL7 of the block Bi may be formed without the flag-like portions F0″ to F7″, wherein the lines are bent over a distance corresponding to one block (the block Bi).

The line width of the word lines WL0 to WL7 at the bent part FV2″ including no flag-like portions F0″ to F7″ may be set almost equal to the width of the word lines WL0 to WL7 in the blocks Bi−1, Bi, and Bi+1. Further, the bent parts FV1″ and FV2″ of the word lines WL0 to WL7 may be provided with the cut part CT3 to cut the word lines WL0 to WL7 for every one of the blocks Bi−1 to Bi+1.

Here, the block Bi and the block Bi−1 or Bi+1 are alternately arranged in the column direction CD, under conditions where the block Bi is configured such that the flag-like portions F0″ to F3″ of the word lines WL0 to WL3 and the flag-like portions F4″ to F7″ of the word lines WL4 to WL7 are led out in directions opposite to each other on one side of the block in the row direction RD, and where each of the blocks Bi−1 and Bi+1 is configured such that the flag-like portions F0″ to F3″ of the word lines WL0 to WL3 and the flag-like portions F4″ to F7″ of the word lines WL4 to WL7 are led out in directions opposite to each other on the other side of the block in the row direction RD. With this arrangement, it becomes unnecessary to arrange the flag-like portions F0″ to F7″ to be sifted in the row direction RD for every set of the word lines WL0 to WL7 of the block Bi. Consequently, the hookup section 10A″ can be shortened in the row direction RD to reduce the layout area.

Further, on the left side of the blocks Bi−1, Bi, and Bi+1, the flag-like portions F0″ to F7″ of the word lines WL0 to WL7 of the block Bi are arranged at positions more distant from the blocks Bi−1, Bi, and Bi+1 as compared with those end portions of the word lines WL0 to WL7 of each of the blocks Bi−1 and Bi+1 which include no flag-like portions F0″ to F7″, and, on the right side of the blocks Bi−1, Bi, and Bi+1, the flag-like portions F0″ to F7″ of the word lines WL0 to WL7 of each of the blocks Bi−1 and Bi+1 are arranged at positions more distant from the blocks Bi−1, Bi, and Bi+1 as compared with those end portions of the word lines WL0 to WL7 of the block Bi which include no flag-like portions F0″ to F7″. With this arrangement, the space of the flag-like portions F0″ to F7″ can be expanded in the column direction CD to enlarge the area of the contacts N0″ to N7″.

In the configuration example shown in FIG. 23, even if the bent part FV2″ is omitted at those end portions of the word lines WL0 to WL7 which include nc flag-like portions F0″ to F7″, the flag-like portions F0″ to F7″ are still set distant from the blocks Bi−1, Bi, and Bi+1 by that much. However, in such a case, the flag-like portions F0″ to F7″ may be shifted toward the blocks Bi−1, Bi, and Bi+1 by that much corresponding to the bent part FV2″.

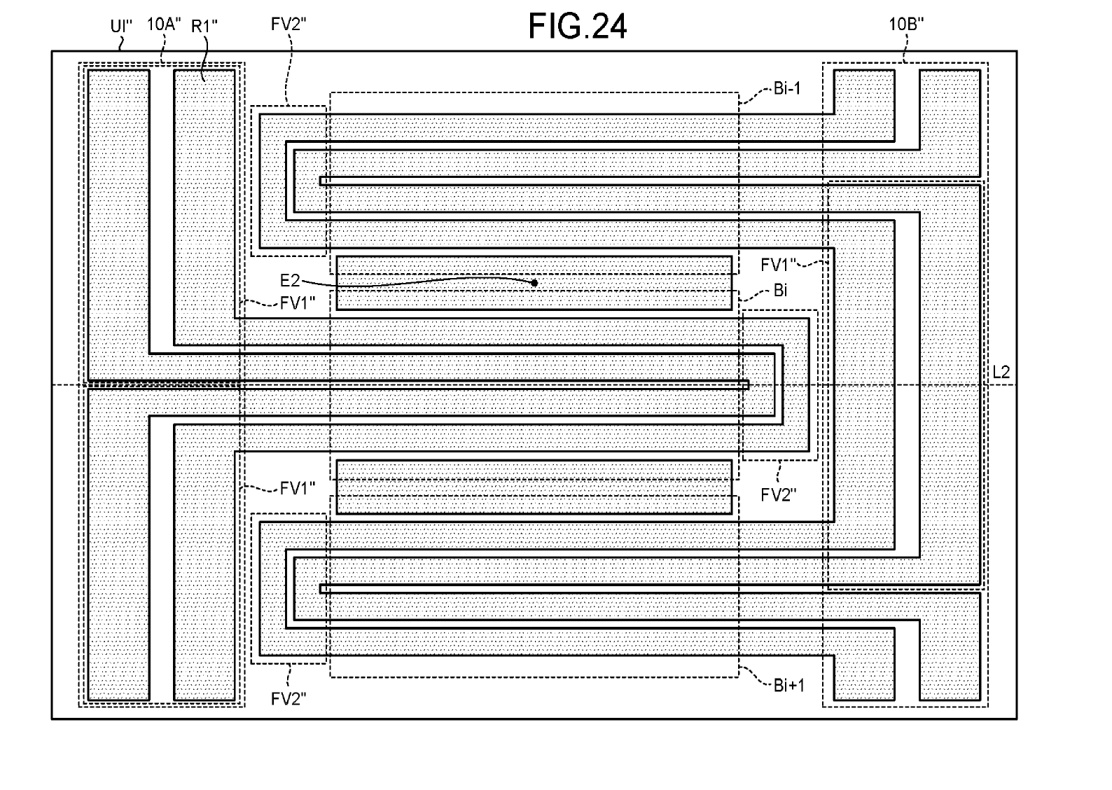

FIGS. 24 to 31 are plan views showing a method of manufacturing the nonvolatile semiconductor memory device according to the third embodiment.

As shown in FIG. 24, a core material pattern R1″ is formed on a process target film UI″. Here, the portions of the core material pattern R1″ corresponding to the flag-like portions F0″ to F7″ for the block Bi may be arranged on one side of the block Bi such that they are in line symmetry relative to the center line L2 of the block Bi. Further, the portions of the core material pattern R1″ corresponding to the flag-like portions F0″ to F7″ for the block Bi and the flag-like portions F0″ to F7″ for the block Bi−1 adjacent to the block Bi may be arranged on the opposite sides of the blocks Bi−1 and Bi such that they are in point symmetry relative to the center E2 between the blocks Bi−1 and Bi. At this time, the portions of the core material pattern R1″ corresponding to the bent part FV1″ of the word lines WL0 to WL7 of each of the blocks Bi−1 and Bi+1 may be formed with a line width to make the flag-like portions F0″ to F7″, wherein the lines are bent over a distance corresponding to two blocks. Further, the portions of the core material pattern R1″ corresponding to the bent part FV2″ of the word lines WL0 to WL7 of each of the blocks Bi−1 and Bi+1 may be formed with a line width smaller than that of the bent part FV1″, wherein the lines are bent over a distance corresponding to one block. On the other hand, the portions of the core material pattern R1″ corresponding to the bent part FV1″ of the word lines WL0 to WL7 of the block Bi may be formed with a line width to make the flag-like portions F0″ to F7″, wherein the lines are bent over a distance corresponding to two blocks. Further, the portions of the core material pattern R1″ corresponding to the bent part FV2″ of the word lines WL0 to WL7 of the block Bi may be formed with a line width smaller than that of the bent part FV1″, wherein the lines are bent over a distance corresponding to one block. The line width of the portions of the core material pattern R1″ corresponding to the bent part FV2″ of the word lines WL0 to WL7 may be set almost equal to the line width of the portions of the core material pattern R1″ corresponding to the blocks Bi−1 to Bi+1. Further, the line width of the portions of the core material pattern R1″ corresponding to the bent part FV1″ of the word lines WL0 to WL7 may be set larger than the line width of the portions of the core material pattern R1″ corresponding to the blocks Bi−1 to Bi+1.

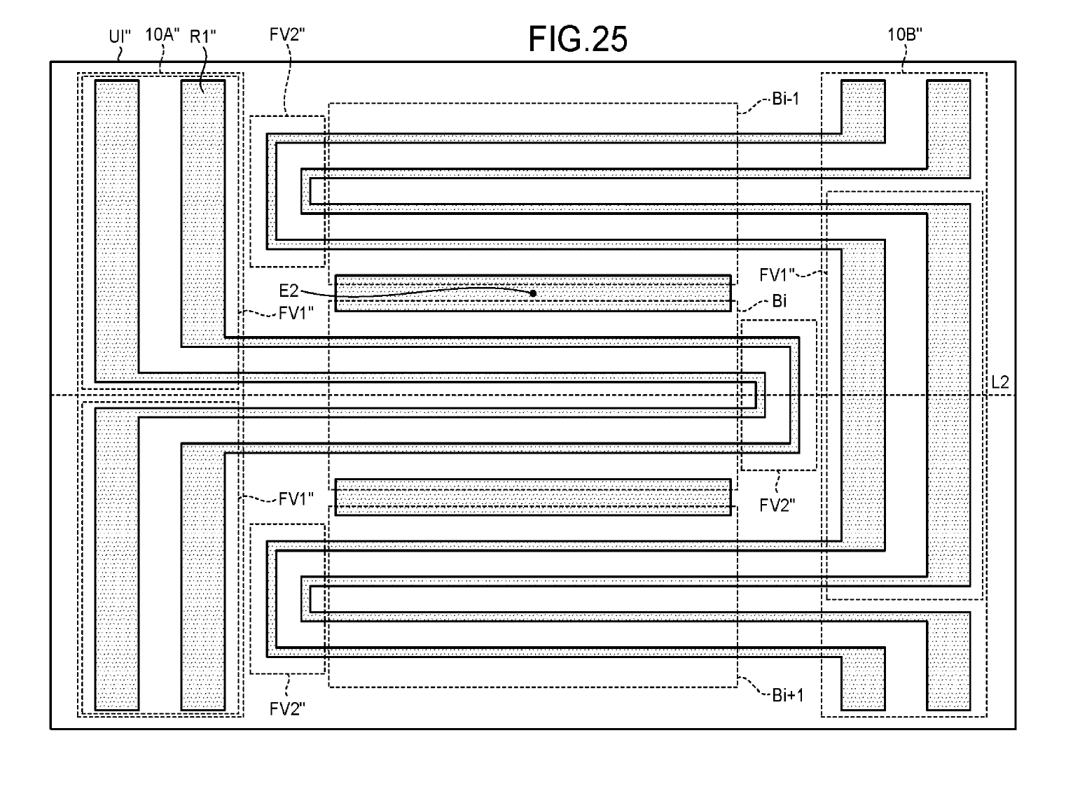

Then, as shown in FIG. 25, slimming of the core material pattern R1″ is performed by use of, e.g., an isotropic etching method to reduce the line width of the core material pattern R1″.

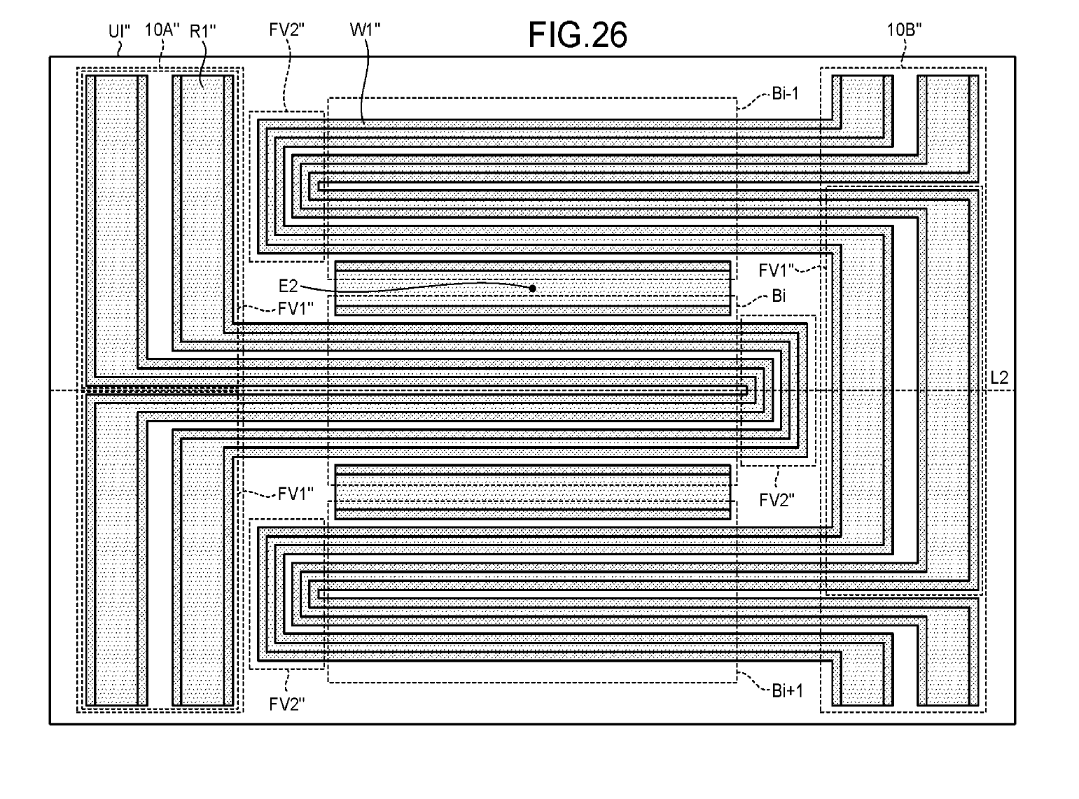

Then, as shown in FIG. 26, a sidewall material high in selectivity relative to the core material pattern R1″ is deposited all over on the process target film UI″ including the sidewall of the core material pattern R1″, by use of, e.g., a CVD method. Then, the sidewall material is etched by anisotropic etching, so that the process target film UI″ is exposed and the sidewall material is still left on the sidewall of the core material pattern R1″. At this time, a sidewall pattern W1″ is formed along the outer periphery of the core material pattern R1″.

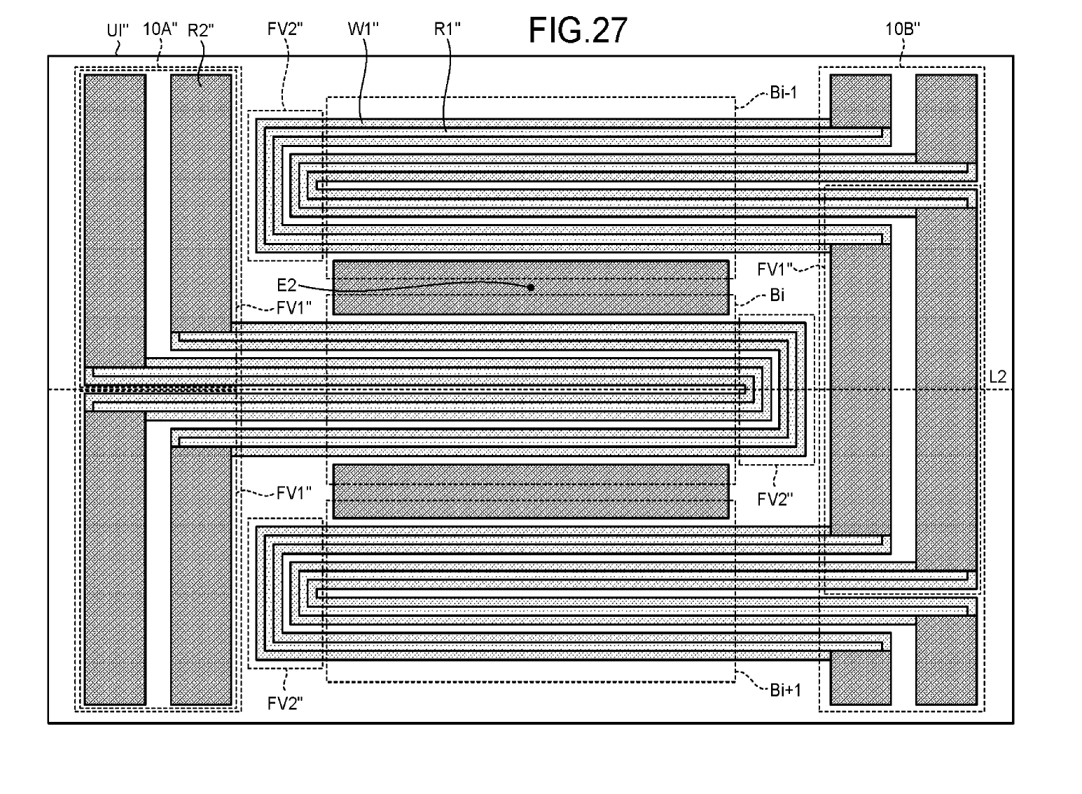

Then, as shown in FIG. 27, a resist film R2″ is formed by use of a photo-lithography technique to cover the portions of the core material pattern R1″ corresponding to the flag-like portions F0″ to F7″ of the word lines WL0 to WL7. At this time, the portions of the core material pattern R1″ corresponding to the selection gate lines SGD and SGS can also be covered with the resist film R2″.

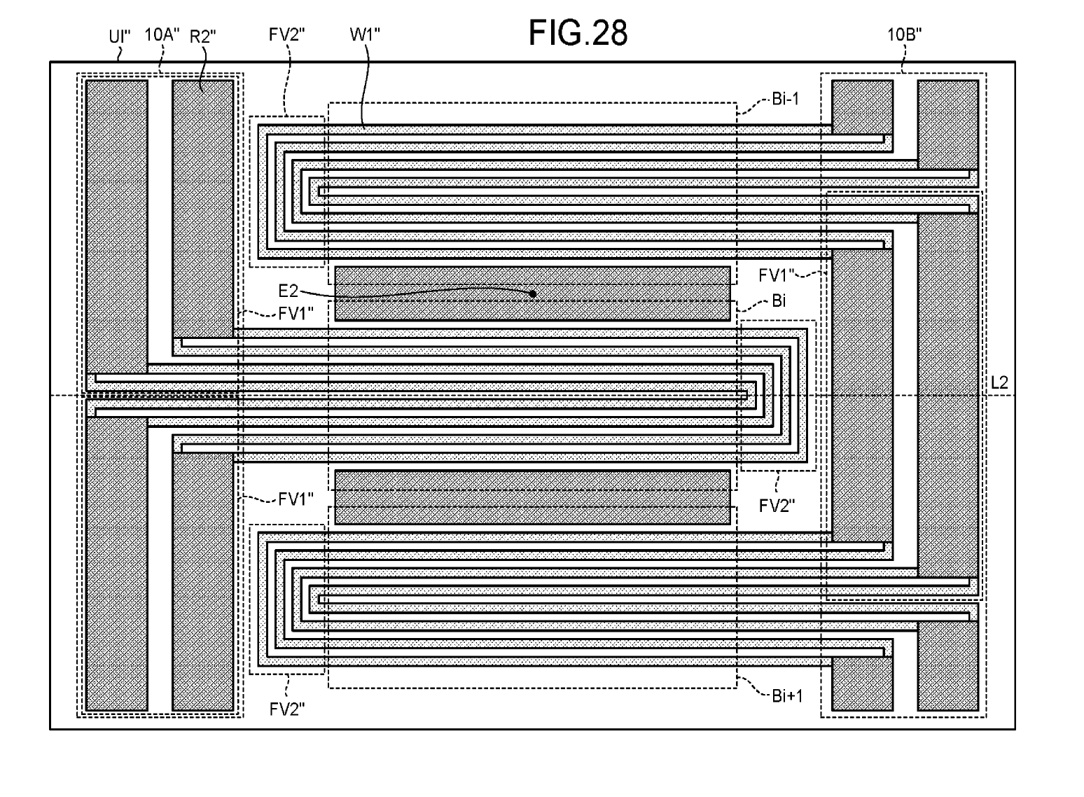

Then, as shown in FIG. 28, part of the core material pattern R1″ on the process target film UI″ is removed by use of an etching technique, such that the sidewall pattern W1″ is still left on the process target film UI″.

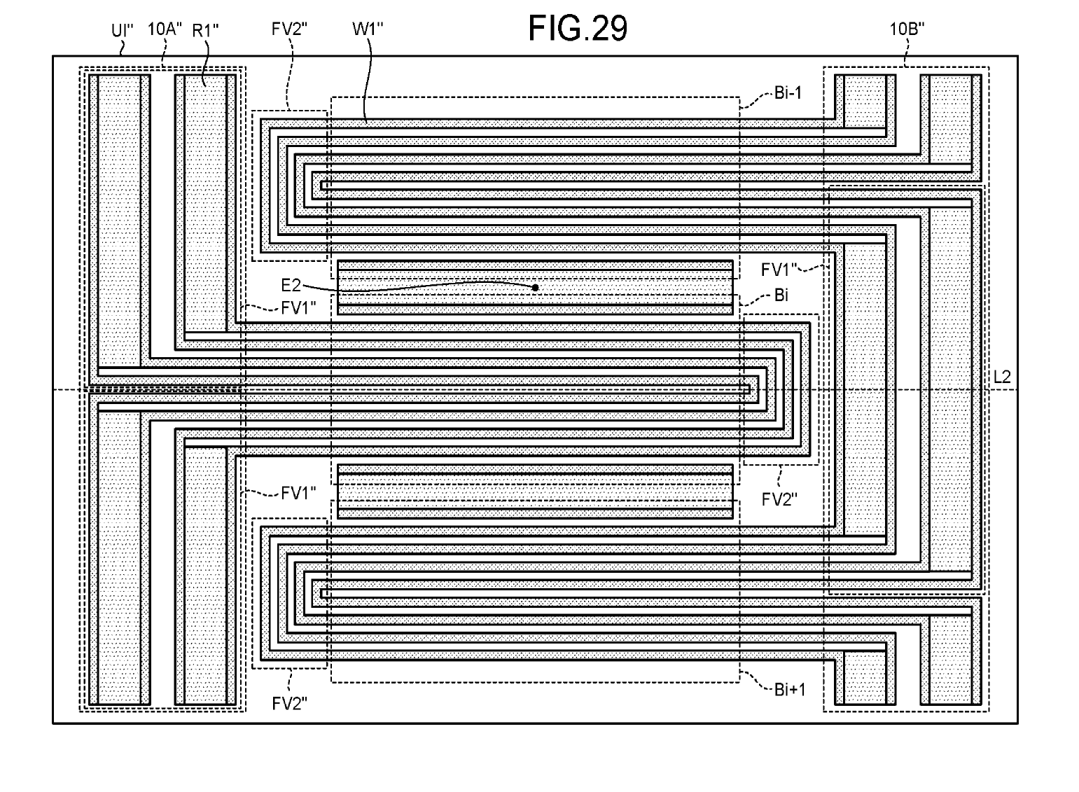

Then, as shown in FIG. 29, the resist film R2″ is removed, so that the portions of the core material pattern R1″ corresponding to the flag-like portions F0″ to F7″ of the word lines WL0 to WL7 are exposed. At this time, the portions of the core material pattern R1″ corresponding to the selection gate lines SGD and SGS can also be exposed.

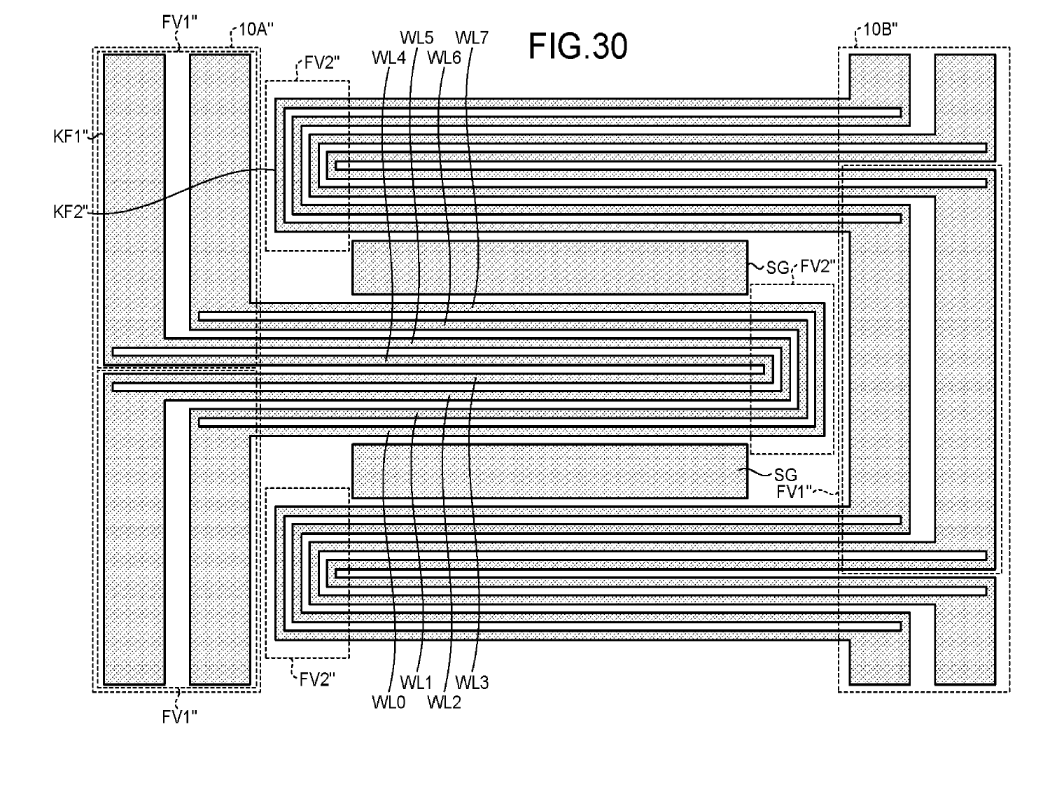

Then, as shown in FIG. 30, while the sidewall pattern W1″, the portions of the core material pattern R1″ corresponding to the flag-like portions F0″ to F7″ of the word lines WL0 to WL7, and the portions of the core material pattern R1″ corresponding to the selection gate lines SGD and SGS are used as a mask, the process target film UI″ is processed to form the word lines WL0 to WL7, selection gate lines SG, and bent parts KF1″ and KF2″.

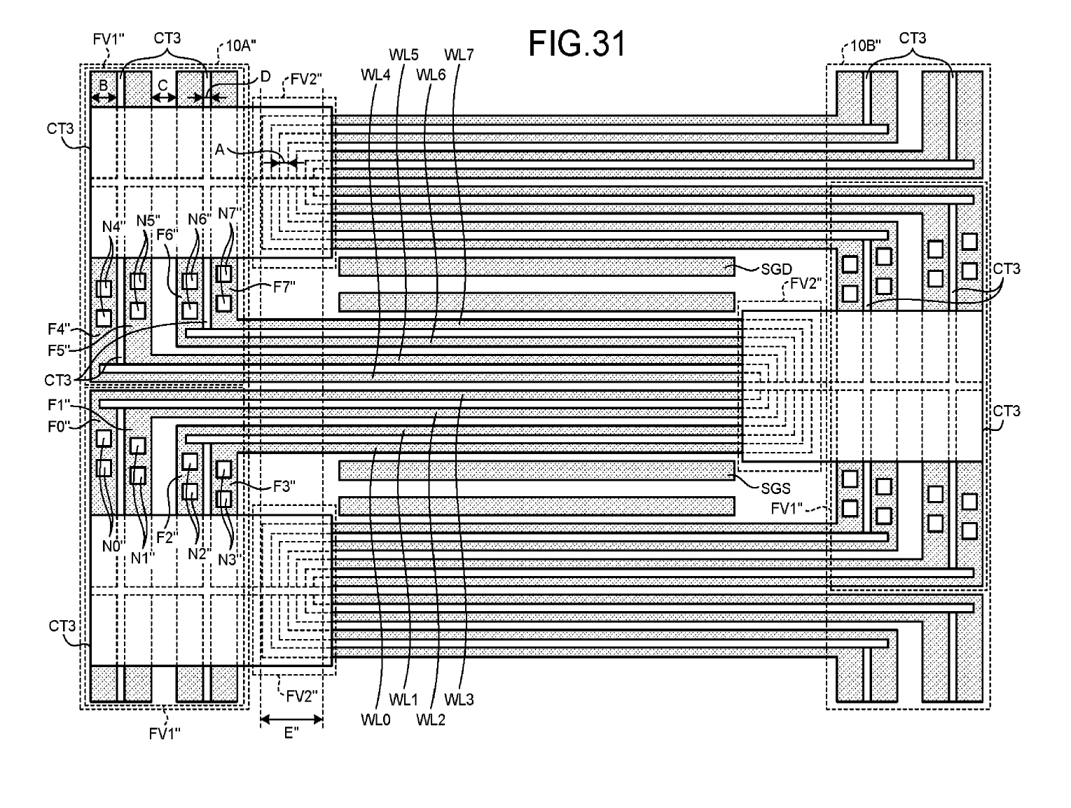

Then, as shown in FIG. 31, the bent parts KF1″ and KF2″ are cut by a cut part CT3 to cut the word lines WL0 to WL7 for every one of the blocks Bi−1 to Bi+1, and to cut the bent part KF1″ into the flag-like portions F0″ to F7″. Further, each of the selection gate lines SG is cut into the selection gate lines SGD and SGS. Then, the contacts N0″ to N7″ are respectively formed in the flag-like portions F0″ to F7″.

Here, for the word lines WL0 to WL7 in the blocks Bi−1 to Bi+1 and the bent part KF2″ of the word lines WL0 to WL7, the line width and the intervals may be set at A. The line width of the flag-like portions F0″ to F7″ may be set at B. The intervals of the flag-like portions F0″ to F7″ may be set at C. The loop cut width of the flag-like portions F0″ to F7″ may be set at D. In this configuration where the bent part FV2″ is not equipped with the flag-like portions F0″ to F7″, the width E″ of the bent part FV2″ can be smaller. For example, if a NAND memory includes 128 word lines per each block, the reduction effect in the row direction width of the bent parts FV1″ and FV2″ of the word lines WL0 to WL7 is expressed by [{(C+D)/2+B}×64]−2A×64.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device comprising:
a block formed with NAND cells arrayed in a row direction, each of the NAND cells including memory cells connected in series in a column direction; and
a section formed with flag-like portions that make contacts with word lines of the memory cells,
wherein the word lines include
first word lines equipped with flag-like portions on one side of the block in the row direction and equipped with no flag-like portions on the other side of the block in the row direction, and
second word lines equipped with no flag-like portions on the one side of the block in the row direction and equipped with flag-like portions on the other side of the block in the row direction, and
wherein the flag-like portions of the first word lines are arranged at positions more distant from the block as compared with end portions of the second word lines, which include no flag-like portions, on the one side of the block in the row direction, and
the flag-like portions of the second word lines are arranged at positions more distant from the block as compared with end portions of the first word lines, which include no flag-like portions, on the other side of the block in the row direction.

2. The nonvolatile semiconductor memory device according to claim 1, wherein the first word lines and the second word lines belong to a same block.

3. The nonvolatile semiconductor memory device according to claim 1, wherein the first word lines the word second lines are respectively formed with a bent part including the flag-like portions and with a bent part including no flag-like portions, and the bent part including the flag-like portions and the bent part including no flag-like portions are bent in directions opposite to each other and are arranged on opposite sides of the block.

4. The nonvolatile semiconductor memory device according to claim 1, wherein flag-like portions for one block are arranged on opposite sides of this block such that these flag-like portions are in point symmetry relative to a center of this block, and flag-like portions for two blocks adjacent to each other are arranged in line symmetry relative to a boundary between these two blocks.

5. The nonvolatile semiconductor memory device according to claim 2, further comprising a first row decoder connected to the first word lines; and a second row decoder connected to the second word lines.

6. The nonvolatile semiconductor memory device according to claim 2, further comprising third word lines arranged between the first word lines and the second word lines and equipped with flag-like portions on opposite sides of the block in the row direction.

7. The nonvolatile semiconductor memory device according to claim 6, further comprising a first row decoder connected to the first word lines and the third word lines; and a second row decoder connected to the second word lines and the third word lines.

8. The nonvolatile semiconductor memory device according to claim 3, wherein the flag-like portions have a width larger than a width of the word lines, and wherein the bent part including no flag-like portions has a width almost equal to a width of the word lines in the block.

9. The nonvolatile semiconductor memory device according to claim 1, wherein the first word lines belong to a first block and the second word lines belong to a second block adjacent to the first block.

10. The nonvolatile semiconductor memory device according to claim 9, wherein the first block is arranged such that one part and the other part of the first word lines are bent in directions opposite to each other on the one side of the first block in the row direction, and the second block is arranged such that one part and the other part of the second word lines are bent in directions opposite to each other on the other side of the second block in the row direction.

11. The nonvolatile semiconductor memory device according to claim 1, wherein flag-like portions for one block are arranged on one side of this block such that these flag-like portions are in line symmetry relative to a center line of this block, and flag-like portions for two blocks adjacent to each other are arranged on opposite sides of these two blocks such that these flag-like portions are in point symmetry relative to a center of these two blocks.

12. The nonvolatile semiconductor memory device according to claim 9, further comprising a first row decoder connected to the first word lines of the first block; and a second row decoder connected to the second word lines of the second block.

13. The nonvolatile semiconductor memory device according to claim 10, wherein the flag-like portions has a width larger than a width of the word lines.

14. A nonvolatile semiconductor memory device comprising:
a block formed with NAND cells arrayed in a row direction, each of the NAND cells including memory cells connected in series in a column direction, and a word line being shared with the memory cells in a same row,
wherein the word lines include
first word lines equipped with contacts on one side of the block in the row direction and equipped with no contacts on the other side of the block in the row direction, and
second word lines equipped with no contacts on the one side of the block in the row direction and equipped with contacts on the other side of the block in the row direction, and
wherein end portions equipped with contacts of the first word lines are arranged at positions more distant from the block as compared with end portions equipped with no contacts of the second word lines on the one side of the block in the row direction, and
end portions equipped with contacts of the second word lines are arranged at positions more distant from the block as compared with end portions equipped with no contacts of the first word lines on the other side of the block in the row direction.

15. A method of manufacturing a nonvolatile semiconductor memory device, which includes a block formed with NAND cells arrayed in a row direction, each of the NAND cells including memory cells connected in series in a column direction, and a section formed with word line led out portions that make contacts with word lines of the memory cells, the method comprising:
providing the word lines with a bent part having a line width corresponding to word line led out portions and with a bent part having a line width smaller than that of the word line led out portions, on each of opposite sides of the block in the row direction, such that the former bent part is formed by extending word lines outward along an outer periphery of the latter bent part.

16. The method of manufacturing a nonvolatile semiconductor memory device according to claim 15, wherein first word lines and second word lines are respectively equipped with the word line led out portions on different sides of the opposite sides of the block, and the method comprises bending the first word lines and the second word lines on opposite sides of blocks alternately for every one block.

17. The method of manufacturing a nonvolatile semiconductor memory device according to claim 16, wherein the method comprises arranging third word lines between the first word lines and the second word lines, such that the third word lines are formed with bent parts having a line width corresponding to the word line led out portions, on the opposite sides of the block.

18. The method of manufacturing a nonvolatile semiconductor memory device according to claim 16, wherein the method comprises:
forming a core material pattern, which includes a sidewall arranged along the word lines, on a process target film;
forming a sidewall pattern on the sidewall of the core material pattern;
forming a resist pattern to cover part of the core material pattern corresponding to the word line led out portion;
removing part of the core material pattern exposed from the resist pattern;
removing the resist pattern after removing part of the core material pattern; and
forming the first word lines and the second word lines by etching the process target film while using, as a mask, part of the core material pattern and the sidewall pattern left after removing the resist pattern.

19. The method of manufacturing a nonvolatile semiconductor memory device according to claim 15, wherein the method comprises:
bending first word lines for every two blocks via a bent part having a line width corresponding to the word line led out portions and bending second word lines for every one block via a bent part having a line width smaller than that of the word line led out portions, on one side of the blocks; and
bending the first word lines for every one block via a bent part having a line width smaller than that of the word line led out portions and bending the second word lines for every two blocks via a bent part having a line width corresponding to the word line led out portions, on the other side of the blocks.

20. The method of manufacturing a nonvolatile semiconductor memory device according to claim 19, wherein the method comprises:
forming a core material pattern, which includes a sidewall arranged along the word lines, on a process target film;
forming a sidewall pattern on the sidewall of the core material pattern;
forming a resist pattern to cover part of the core material pattern corresponding to the word line led out portions;
removing part of the core material pattern exposed from the resist pattern;
removing the resist pattern after removing part of the core material pattern; and
forming the first word lines and the second word lines by etching the process target film while using, as a mask, part of the core material pattern and the sidewall pattern left after removing the resist pattern.
